(19) United States
(12) Patent Application Publication
(10) Pub. No.: US 2016/0118331 A1
(43) Pub. Date: Apr. 28, 2016

(54) SEMICONDUCTOR DEVICE AND METHOD OF MANUFACTURING THE SAME

(71) Applicant: Samsung Electronics Co., Ltd., Suwon-si (KR)

(72) Inventors: Young-kuk KIM, Seoul (KR); Chan-mi LEE, Suwon-si (KR); Sang-kwan KIM, Seoul (KR); Young-wook PARK, Osan-si (KR)

(21) Appl. No.: 14/695,281

(22) Filed: Apr. 24, 2015

(30) Foreign Application Priority Data
Oct. 28, 2014 (KR) 10-2014-0147623

(51) Int. Cl. H01L 23/528; H01L 27/088

(52) U.S. Cl. CPC H01L 23/528; H01L 27/088

(57) ABSTRACT

A semiconductor device includes a substrate including a cell array region having a first active region and a peripheral circuit region having a second active region, an insulating layer pattern on the substrate and including a hole corresponding with the first active region, a DC conductive pattern in the hole, connected to the first active region, and buried in the substrate, a bit line connected to the DC conductive pattern and including a first bit line conductive pattern contacting the DC conductive pattern and covering a top surface of the insulating layer pattern, and a gate insulating layer and a gate electrode structure on the second active region, the gate electrode structure including a gate conductive pattern and a first gate electrode conductive pattern, the first gate electrode conductive pattern including a same material as the first bit line conductive pattern.

### CROSS-REFERENCE TO RELATED APPLICATION

This application claims the benefit of Korean Patent Application No. 10-2014-0147623, filed on Oct. 28, 2014, in the Korean Intellectual Property Office, the disclosure of which is incorporated herein in its entirety by reference.

### BACKGROUND

1. Field

Some example embodiments of the inventive concepts relate to a semiconductor device and a method of manufacturing the same, and more particularly, to a semiconductor device including a bit line and a direct contact (DC) conductive pattern configured to connect the bit line with an active region, and a method of manufacturing the same.

2. Description of the Related Art

With an increase in the integration density of semiconductor devices, design rules of elements of the semiconductor devices have been reduced. In a highly integrated semiconductor device, during formation of a bit line and a DC conductive pattern configured to connect the bit line with an active region, a seam may be formed in the DC conductive pattern or the height of a bit line structure may unnecessarily increase. To solve such problems, additional processes may be required, thereby complicating a semiconductor manufacturing process.

### SUMMARY

Some example embodiments of the inventive concepts provide a semiconductor device having a unit cell size that is miniaturized due to an increase in integration density, which may prevent or inhibit formation of seams in direct contact (DC) conductive patterns and reduce the height of a bit line structure.

Other example embodiments of the inventive concepts also provide a method of manufacturing a semiconductor device, by which a DC conductive pattern having no structural failures may be formed using a simplified process in a semiconductor device having a unit cell size that is reduced due to an increase in integration density, and the height of a bit line structure may be reduced.

According to an example embodiment of the inventive concepts, a semiconductor device includes a substrate including a cell array region having a first active region and a peripheral circuit region having a second active region, an insulating layer pattern on the substrate in the cell array region, the insulating layer pattern including a hole corresponding with the first active region, a direct contact (DC) conductive pattern in the hole and connected to the first active region in the cell array region, the DC conductive pattern buried in the substrate, a bit line connected to the DC conductive pattern in the cell array region, the bit line including a first bit line conductive pattern contacting the DC conductive pattern and covering a top surface of the insulating layer pattern, a gate insulating layer on the second active region in the peripheral circuit region, and a gate electrode structure on the gate insulating layer in the peripheral circuit region, the gate electrode structure including a gate conductive pattern contacting the gate insulating layer, and a first gate electrode conductive pattern on the gate conductive pattern, the first gate electrode conductive pattern including a same material as the first bit line conductive pattern.

The DC conductive pattern may have a top surface that extends on a same plane as the top surface of the insulating layer pattern, and the first bit line conductive pattern may have a bottom surface contacting the top surface of the DC conductive pattern.

The DC conductive pattern may be integrally connected to the first bit line conductive pattern. The first bit line conductive pattern may have a first thickness in a first direction perpendicular to the substrate, and a sum of thicknesses of the gate conductive pattern and the first gate electrode conductive pattern obtained in the first direction may be greater than the first thickness.

The DC conductive pattern may include an epitaxial silicon layer. The DC conductive pattern and the first bit line conductive pattern may include a same material. The bit line may further include a second bit line conductive pattern and a third bit line conductive pattern sequentially formed on the first bit line conductive pattern, the gate electrode structure may further include a second gate electrode conductive pattern and a third gate electrode conductive pattern sequentially formed on the first gate electrode conductive pattern, the second gate electrode conductive pattern may include a same material as the second bit line conductive pattern, and the third gate electrode conductive pattern may include a same material as the third bit line conductive pattern.

The DC conductive pattern may include an epitaxial silicon layer, and each of the first bit line conductive pattern, the gate conductive pattern, and the first gate electrode conductive pattern may include conductive poly-Si.

According to another example embodiment of the inventive concepts, a method of manufacturing a semiconductor device includes preparing a substrate having a cell array region including a first active region and a peripheral circuit region including a second active region, forming an insulating layer pattern on the cell array region and the peripheral circuit region of the substrate, the insulating layer pattern including a hole exposing the first active region of the cell array region, forming a direct contact (DC) hole by etching the substrate through the hole of the cell array region, forming a DC conductive pattern in the DC hole, exposing the second active region by removing a portion of the insulating layer pattern in the peripheral circuit region, sequentially forming a gate insulating layer, a gate conductive layer and a gate electrode conductive layer to cover the second active region in the peripheral circuit region, forming a bit line conductive layer connected to the DC conductive pattern in the cell array region and contacting the gate electrode conductive layer in the peripheral circuit region, forming a bit line connected to the DC conductive pattern by patterning the bit line conductive layer in the cell array region, and forming a gate electrode structure by patterning the gate conductive layer and the gate electrode conductive layer in the peripheral circuit region.

The gate insulating layer, the gate conductive layer and the gate electrode conductive layer may be sequentially formed to cover the second active region in the peripheral circuit region by sequentially forming the gate insulating layer and the gate conductive layer on the substrate in the cell array region and the peripheral circuit region to cover the DC conductive pattern in the cell array region and cover the second active region in the peripheral circuit region, and exposing the DC conductive pattern in the cell array region by removing portions of the gate insulating layer and the gate conductive layer in the cell array region.

The DC conductive pattern may be formed using a bottom-up method. The bit line conductive layer may be formed by forming a first bit line conductive layer contacting a top surface of the DC conductive pattern and the gate conductive layer in the peripheral circuit region, the top surface of the DC conductive pattern extending on a same plane as a top surface of the insulating layer pattern in the cell array region, wherein the first bit line conductive layer includes a same material as the DC conductive pattern.

The first bit line conductive layer may include a same material as the gate conductive layer. Forming the bit line conductive layer may include forming a first bit line conductive layer contacting a top surface of the DC conductive pattern and the gate conductive layer in the peripheral circuit region, the top surface of the DC conductive pattern extending on a same plane as a top surface of the insulating layer pattern in the cell array region, and forming at least one second bit line conductive layer to cover the first bit line conductive layer in the cell array region and the peripheral circuit region. Forming the bit line may include patterning the first bit line conductive layer and the at least one second bit line conductive layer to form the bit line including a plurality of first and second bit line conductive patterns sequentially stacked on the substrate.

Forming the gate electrode structure may include patterning the gate conductive layer, the first bit line conductive layer, and the at least one second bit line conductive layer to form the gate electrode structure including at least three gate conductive patterns sequentially stacked on the substrate.

According to another example embodiment of the inventive concepts, a semiconductor device includes an insulating layer pattern on an active region in a substrate, the insulating layer pattern including a hole exposing the active region, an epitaxial silicon pattern filling the hole and connected to the active region, the epitaxial silicon pattern buried in the substrate, and a bit line connected to the epitaxial silicon pattern, the bit line including at least one conductive pattern contacting the epitaxial silicon pattern.

The epitaxial silicon pattern may have a top surface that extends on a same plane as the top surface of the insulating layer pattern, and the conductive pattern may have a bottom surface contacting the top surface of the epitaxial silicon pattern.

The epitaxial silicon pattern may be integrally connected to the conductive pattern. The epitaxial silicon pattern and the conductive pattern may include a same material. The conductive pattern may include conductive poly-Si.

### BRIEF DESCRIPTION OF THE DRAWINGS

Example embodiments of the inventive concepts will be more clearly understood from the following detailed description taken in conjunction with the accompanying drawings in which:

FIG. 1 is a schematic plan layout of main elements of a cell array region of a semiconductor device according to example embodiments of the inventive concepts;

FIG. 2 is a cross-sectional view of essential parts of a semiconductor device according to example embodiments of the inventive concepts;

FIG. 3 is a cross-sectional view of essential parts of a semiconductor device according to example embodiments of the inventive concepts;

FIGS. 4 through 12 are cross-sectional views of sequential processes of a method of manufacturing a semiconductor device according to example embodiments of the inventive concepts;

FIGS. 13 through 17 are cross-sectional views of sequential processes of a method of manufacturing a semiconductor device according to other example embodiments of the inventive concepts;

FIGS. 18 through 20 are cross-sectional views of sequential processes of a method of manufacturing a semiconductor device according to other example embodiments of the inventive concepts;

FIG. 21 is a diagram of a system including a semiconductor device according to an example embodiment of the inventive concepts; and

FIG. 22 is a diagram of a memory card including a semiconductor device according to an example embodiment of the inventive concepts.

### DETAILED DESCRIPTION

The inventive concepts will now be described more fully with reference to the accompanying drawings, in which example embodiments of the inventive concepts are shown. The inventive concepts may, however, be embodied in many different forms and should not be construed as being limited to the embodiments set forth herein; rather, these embodiments are provided so that this disclosure will be thorough and complete, and will fully convey the inventive concepts to those skilled in the art. Like reference numerals in the drawings denote like elements, and descriptions thereof will be omitted.

It will be understood that, although the terms first, second, etc. may be used herein to describe various elements, components, regions, layers and/or sections, these elements, components, regions, layers and/or sections should not be limited by these terms. Thus, a first element, component, region, layer or section discussed below could be termed a second element, component, region, layer or section without departing from the teachings of the inventive concepts.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and this specification and will not be interpreted in an idealized or overly formal sense unless explicitly so defined herein.

Unless explicitly defined in a specific order herein, respective steps described in the inventive concepts may be performed otherwise. That is, the respective steps may be performed in a specified order, substantially at the same time, or in reverse order.

Variations from the shapes of the illustrations as a result, for example, of manufacturing techniques and/or tolerances, are to be expected. Thus, embodiments of the inventive concepts should not be construed as limited to the particular shapes of regions illustrated herein but are to include deviations in shapes that result, for example, from manufacturing. As used herein, the term “and/or” includes any and all combinations of one or more of the associated listed items.

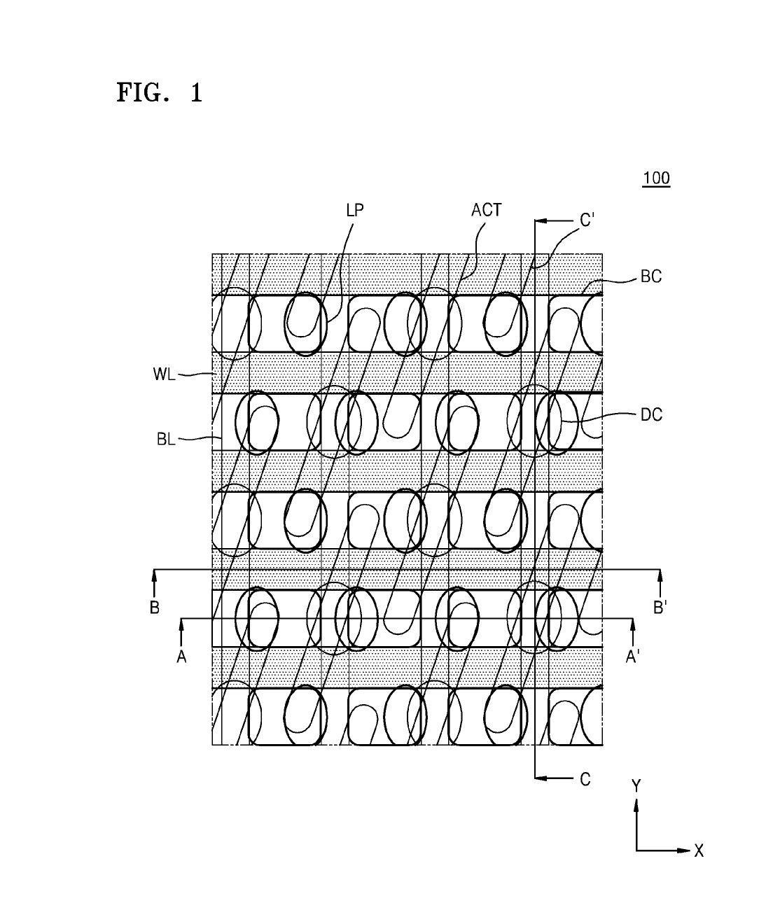

FIG. 1 is a schematic plan layout of main elements of a cell array region of a semiconductor device 100 according to example embodiments of the inventive concepts.

Referring to FIG. 1, the semiconductor device 100 may include a plurality of active regions ACT. The plurality of active regions ACT may be disposed in a direction that is oblique to each of a first direction (X direction) and a second direction (Y direction).

A plurality of word lines WL may run across the plurality of active regions ACT and extend parallel to one another in the first direction (X direction). A plurality of bit lines BL may be disposed on the plurality of word lines WL and extend parallel to one another in the second direction (Y direction) that intersects the first direction (X direction).

The plurality of bit lines BL may be connected to the plurality of active regions ACT through direct contacts DC.

In some example embodiments, each of a plurality of buried contacts BC may be formed between two adjacent bit lines BL. Each of the plurality of buried contacts BC may extend onto any one of the two adjacent bit lines BL. In some example embodiments, the plurality of buried contacts BC may be arranged in a matrix shape in a first direction (X direction) and a second direction (Y direction).

A plurality of landing pads LP may be formed on the plurality of buried contacts BC. The plurality of buried contacts BC and the plurality of landing pads LP may serve to connect lower electrodes (not shown) of capacitors formed on the plurality of bit lines BL with the active regions ACT. The plurality of landing pads LP may be disposed to partially overlap the buried contacts BC, respectively.

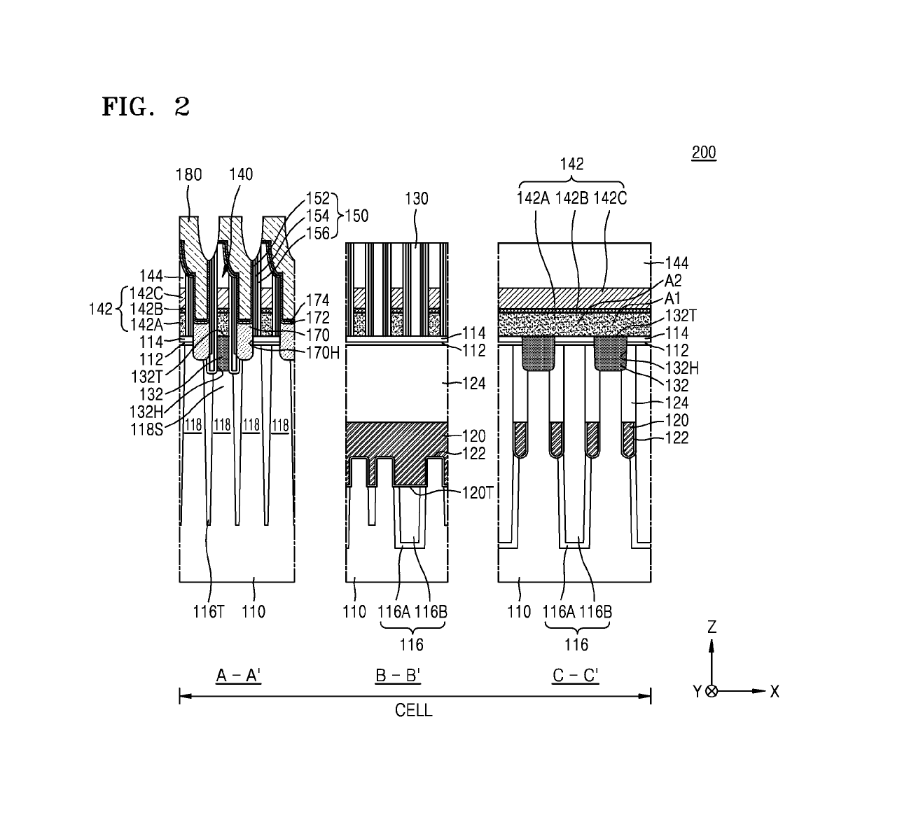

FIG. 2 is a cross-sectional view of essential parts of a semiconductor device 200 according to an example embodiment of the inventive concepts.

A cell array region of the semiconductor device 200 shown in FIG. 2 may have a layout of the semiconductor device 100 shown in FIG. 1. FIG. 2 shows examples of cross-sectional views of some elements, which are taken along lines A-A′, B-B′, and C-C′ of FIG. 1.

Referring to FIG. 2, the semiconductor device 200 may include a substrate 110 in which a plurality of active regions 118 are defined by an isolation layer 116 formed in the isolation trenches 116T. The plurality of active regions 118 may correspond to a plurality of active regions ACT shown in FIG. 1. The isolation layer 116 may include a first isolation layer 116A and a second isolation layer 116B.

In some example embodiments, the substrate 110 may include silicon, for example, single crystalline silicon, polycrystalline silicon (poly-Si), or amorphous silicon (a-Si). In some other embodiments, the substrate 110 may include at least one selected from the group consisting of germanium (Ge), silicon germanium (SiGe), silicon carbide (SiC), gallium arsenide (GaAs), indium arsenide (InAs), and indium phosphide (InP). In some example embodiments, the substrate 110 may include a conductive region, for example, a doped well or a doped structure.

A plurality of trenches 120T may be formed in the substrate 110 and extend in a first direction (X direction of FIG. 1), and a plurality of gate dielectric layers 122 and a plurality of word lines 120 may be formed in the plurality of trenches 120T. The plurality of word lines 120 may constitute the plurality of word lines WL shown in FIG. 1.

A plurality of direct contact (DC) holes 132H may be formed in the substrate 110 and expose portions of the active regions 118, for example, a source region 118S. The plurality of DC holes 132H may be filled with DC conductive patterns 132, respectively. The plurality of DC conductive patterns 132 may constitute the direct contacts DC shown in FIG. 1.

A first buffer insulating layer pattern 112 and a second buffer insulating layer pattern 114 may be sequentially formed on the substrate 110. Each of the first buffer insulating layer pattern 112 and the second buffer insulating layer pattern 114 may include silicon oxide, silicon nitride, or a combination thereof.

A plurality of bit lines 142 may be formed on the second buffer insulating layer pattern 114 and extend parallel to one another in a second direction (Y direction of FIG. 1). The plurality of bit lines 142 may correspond to the plurality of bit lines BL shown in FIG. 1. The plurality of bit lines 142 may be connected to the active regions 118 through the DC conductive patterns 132, respectively.

Each of the plurality of DC conductive patterns 132 may have a top surface 132T that may extend on the same plane with a top surface of the second buffer insulating layer pattern 114.

In some example embodiments, the DC conductive patterns 132 may include silicon (Si), germanium (Ge), tungsten (W), tungsten nitride (WN), cobalt (Co), nickel (Ni), aluminum (Al), molybdenum (Mo), ruthenium (Ru), titanium (Ti), titanium nitride (TiN), tantalum (Ta), tantalum nitride (TaN), copper (Cu), or a combination thereof. In some example embodiments, the DC conductive patterns 132 may include an epitaxial silicon layer.

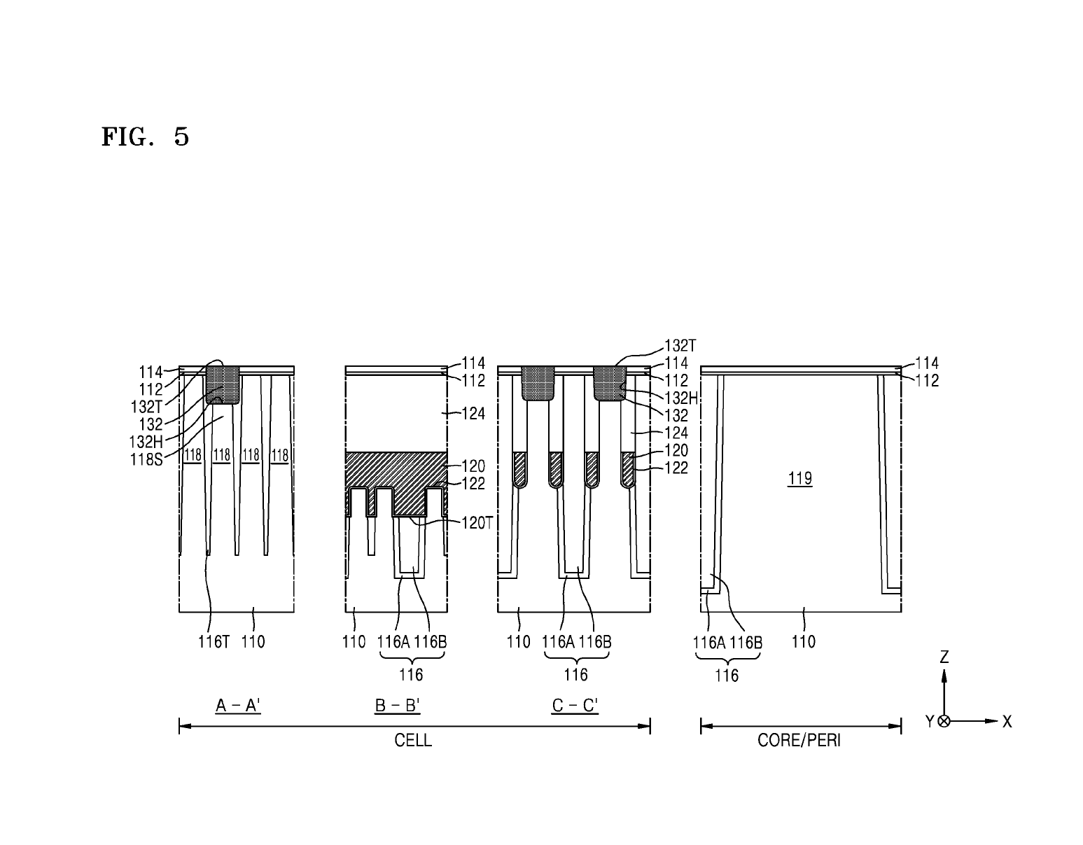

The DC conductive patterns 132 may be formed using a bottom-up method. During the formation of the DC conductive patterns 132, seams may be effectively prevented or inhibited from being formed in the DC conductive patterns 132. Thus, when the plurality of bit lines 142 are formed in a subsequent process, a bit line bridge phenomenon, which may occur when a conductive material for forming the bit lines flows into the seams, may be effectively prevented or inhibited. Accordingly, reliability of the semiconductor device 200 may be improved. Also, when seams are formed in the DC conductive patterns 132, an inevitable attendant process, for example, a silicon/germanium ion implantation process for filling voids formed due to the seams, may be omitted. Accordingly, time and costs taken for a process of manufacturing the semiconductor device 200 may be reduced as will be described in further detail later with reference to FIGS. 5 through 9.

Each of the plurality of bit lines 142 may include a first bit line conductive pattern 142A, which may contact the top surface 132T of the DC conductive pattern 132, which may extend on the same plane with the top surface of the second buffer insulating layer pattern 114. Each of the plurality of bit lines 142 may further include a second bit line conductive pattern 142B and a third bit line conductive pattern 142C, which may sequentially cover the first bit line conductive pattern 142A. FIG. 2 illustrates a case in which each of the plurality of bit lines 142 has a triple conductive stack structure including the first bit line conductive pattern 142A, the second bit line conductive pattern 142B, and the third bit line conductive pattern 142C, but the inventive concepts are not limited thereto. For example, each of the plurality of bit lines 142 may include a single layer, a double layer, or a multilayered stack structure including at least four layers.

In each of the plurality of bit lines 142, the first bit line conductive pattern 142A may include a first portion A1, which may contact the top surface 132T of the DC conductive pattern 132 that may extend on the same plane with the top surface of the second buffer insulating layer pattern 114, and a second portion A2, which may be integrally connected to the first portion A2 and spaced apart from the substrate 110 having the first buffer insulating layer pattern 112 and the second buffer insulating layer pattern 114 therebetween.

In some example embodiments, the first bit line conductive pattern 142A may be formed of conductive poly-Si. The second bit line conductive pattern 142B may be formed of titanium nitride (TiN). The third bit line conductive pattern 142C may be formed of tungsten (W).

The top surface 132T of the DC conductive pattern 132, which may extend on the same plane with the top surface of the second buffer insulating layer pattern 114, may be in direct contact with a bottom surface of the first portion A1 of the first bit line conductive pattern 142A included in each of the plurality of bit lines 142. The bottom surface of the first portion A1 may face the substrate 110.

Insulating capping lines 144 may be respectively formed on the plurality of bit lines 142. One bit line 142 and one insulating capping line 144 covering the one bit line 142 may constitute one bit line structure 140.

Two sidewalls of each of the plurality of bit line structures 140 may be covered with insulating spacer structures 150. Each of the plurality of insulating spacer structures 150 may include first insulating spacers 152, second insulating spacers 154, and third insulating spacers 156. In some example embodiments, each of the first insulating spacers 152, the second insulating spacers 154, and the third insulating spacers 156 may include an oxide layer, a nitride layer, or a combination thereof. In some other embodiments, each of the first insulating spacers 152 and the third insulating spacers 156 may include an oxide layer, a nitride layer, or a combination thereof, and the second insulating spacers 154 interposed between the first insulating spacers 152 and the third insulating spacers 156 may include air spacers.

A plurality of insulating patterns 130 and a plurality of buried contact (BC) holes 170H may be formed in spaces between the plurality of bit lines 142. The plurality of BC holes 170H may be defined by the plurality of insulating patterns 130. An inner space of each of the plurality of BC holes 170H may be confined by the insulating spacer structure 150 and the active region 118, which may cover sidewalls of each of two adjacent bit lines 142, between the two adjacent bit lines 142.

A plurality of buried contacts 170 and a plurality of landing pads 180 may be formed in the plurality of buried contact holes 170H between the plurality of bit lines 142 and respectively connected to the plurality of active regions 118. The plurality of buried contacts 170 and the plurality of landing pads 180 may respectively correspond to the plurality of buried contacts BC and the plurality of landing pads LP shown in FIG. 1.

The plurality of buried contacts 170 may extend from the active region 118 in a third direction (Z direction in FIG. 2) perpendicular to the substrate 110. The plurality of landing pads 180 may be disposed on the buried contacts 170 and extend onto the plurality of bit lines 142, respectively. The plurality of landing pads 180 may be connected to the active region 118 through the buried contacts 170.

The landing pads 180 may extend in a third direction (Z direction in FIG. 2), which is perpendicular to a main surface of the substrate 110 in regions between the plurality of bit lines 142, and cover at least portions of top surfaces of the plurality of bit lines 142 to vertically overlap at least portions of the plurality of bit lines 142.

A metal silicide layer 172 may be formed between the buried contacts 170 and the landing pads 180. The metal silicide layer 172 may be formed of cobalt silicide (CoSix), nickel silicide (NiSix), or manganese silicide (MnSix), but the inventive concepts are not limited thereto.

A conductive barrier layer 174 may be interposed between the landing pads 180 and the insulating spacer structures 150 and between the landing pads 180 and the plurality of bit line structures 140. The conductive barrier layer 174 may be formed of a metal, a conductive metal nitride, or a combination thereof. For example, the conductive barrier layer 174 may have a Ti/TiN stack structure.

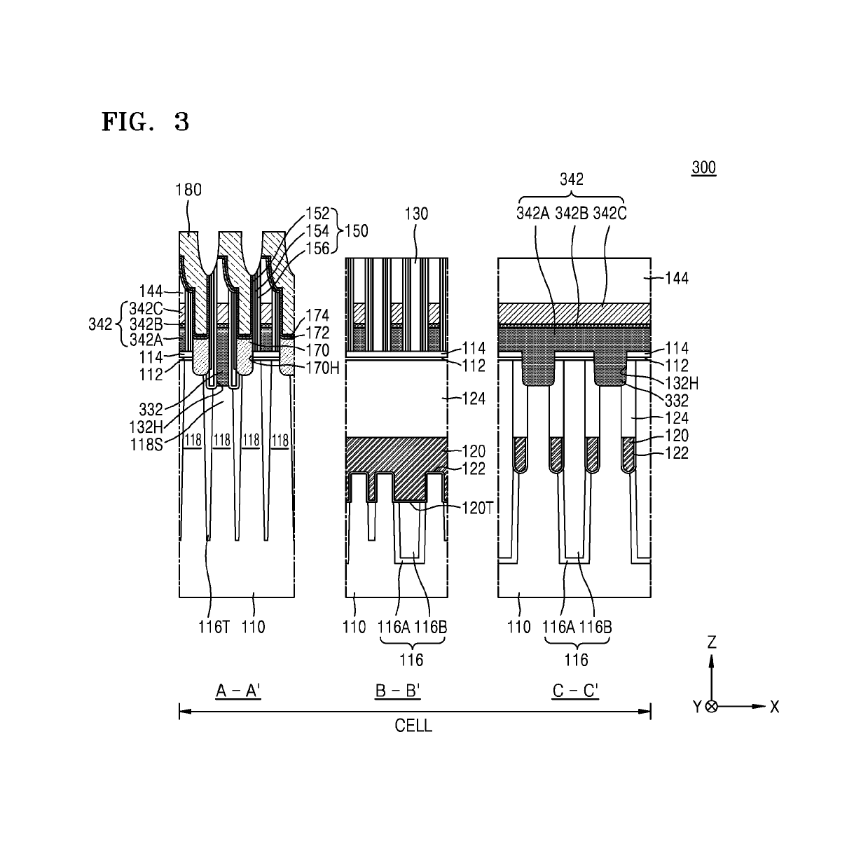

FIG. 3 is a cross-sectional view of essential parts of a semiconductor device 300 according to another example embodiment of the inventive concepts.

A cell array region of the semiconductor device 300 shown in FIG. 3 may have a layout of the semiconductor device 100 shown in FIG. 1. FIG. 3 shows examples of cross-sectional views of some elements, which are taken along lines A-A′, B-B′, and C-C′ of FIG. 1. In FIG. 3, the same reference numerals are used to denote the same elements as in FIG. 2, and detailed descriptions thereof are omitted.

Referring to FIG. 3, the semiconductor device 300 may include a plurality of DC conductive patterns 332 corresponding to direct contacts DC shown in FIG. 1, and a plurality of bit lines 342 corresponding to the plurality of bit lines BL shown in FIG. 1. Each of the plurality of DC conductive patterns 332 may be formed within a DC hole 132H.

Each of the plurality of bit lines 342 may include a first bit line conductive pattern 342A that may be integrally connected to one of the plurality of DC conductive patterns 332, which may vertically overlap the corresponding bit line 342. First bit line conductive patterns 342A included in the bit lines 342 may be integrally connected to the plurality of DC conductive patterns 332. Since the first bit line conductive patterns 342A may be unified with the plurality of DC conductive patterns 332, there may be no interfaces between the first bit line conductive patterns 342A and the plurality of DC conductive patterns 332, and a contact resistance therebetween may be reduced.

Each of the plurality of bit lines 342 may further include a second bit line conductive pattern 342B and a third bit line conductive pattern 342C that may sequentially cover the first conductive pattern 342A. FIG. 3 illustrates an example in which each of the plurality of bit lines 342 has a triple structure including the first bit line conductive pattern 342A, the bit line second conductive pattern 342B, and the third bit line conductive pattern 342C, but the inventive concepts are not limited thereto. For example, each of the plurality of bit lines 342 may include a single layer, a double layer, or a multilayered stack structure including at least four layers.

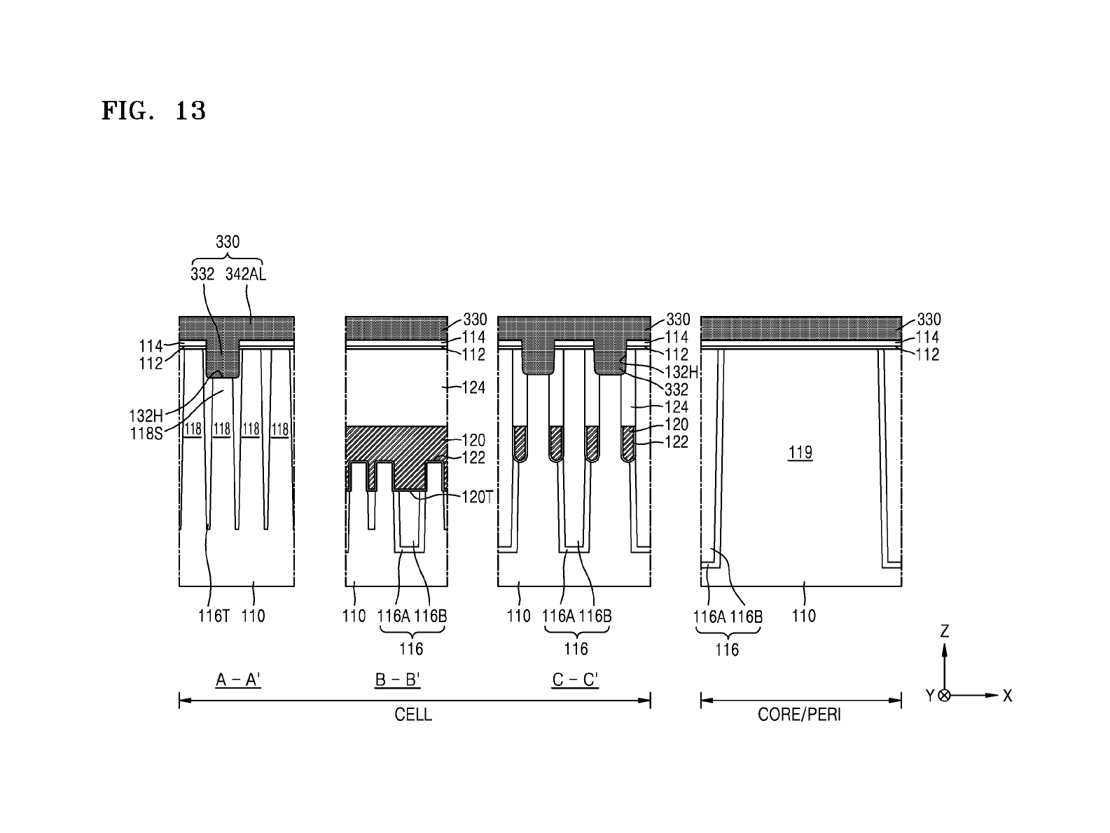

Furthermore, similar to the DC conductive patterns 132 described with reference to FIG. 2, the DC conductive patterns 332 may include an epitaxial silicon layer. Since the DC conductive patterns 332 may be formed by using a bottom-up method, seams may be effectively prevented or inhibited from being formed in the DC conductive patterns 332 during the formation of the DC conductive patterns 332. Thus, when the plurality of bit lines 342 are formed in a subsequent process, a bit line bridge phenomenon, which may occur when a conductive material for forming bit lines flows into the seams, may be effectively prevented or inhibited. Accordingly, reliability of the semiconductor device 300 may be improved. Also, when the seams are formed in the DC conductive patterns 332, an inevitable attendant process may be omitted, thereby reducing the time and costs taken for a process of manufacturing the semiconductor device 300. Examples of processes of forming the DC conductive patterns 332 and the bit lines 342 including the first bit line conductive patterns 342A to be integrally connected to the DC conductive patterns 332 will be described later with reference to FIGS. 13 to 20.

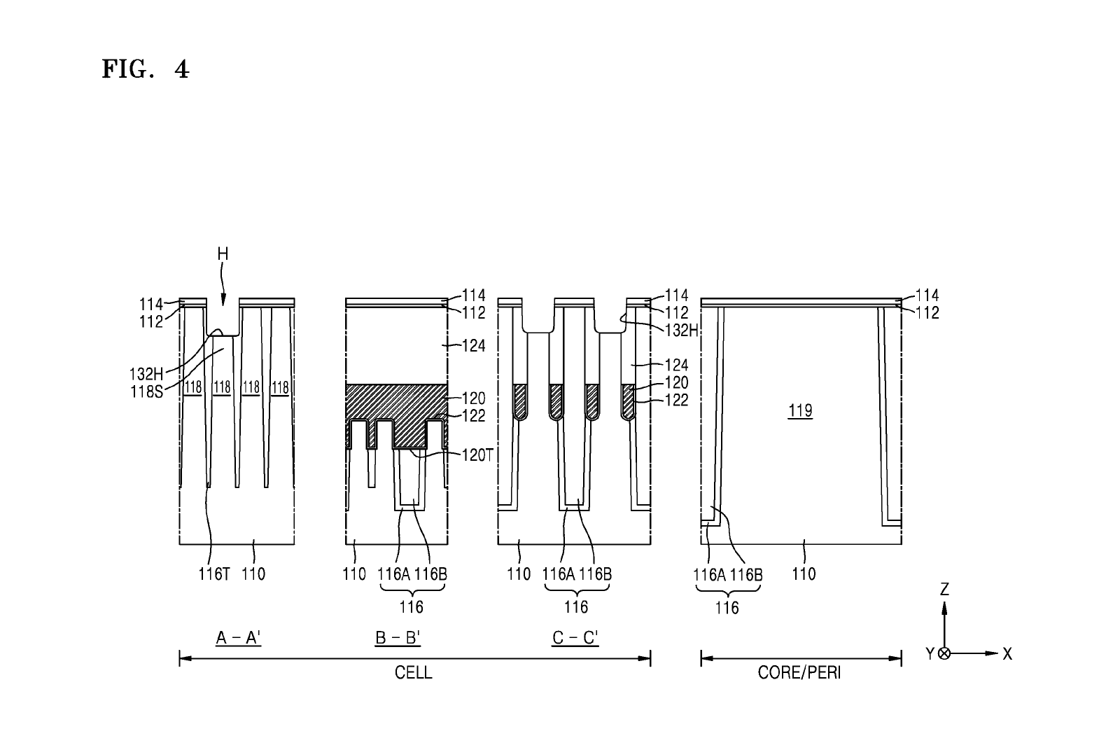

FIGS. 4 to 12 are cross-sectional views of sequential processes of a method of manufacturing a semiconductor device according to example embodiments of the inventive concepts. A method of manufacturing the semiconductor device 200 shown in FIG. 2 will be described with reference to FIGS. 4 through 12.

FIGS. 4 to 12 show cross-sectional views illustrating sequential processes of forming some elements of a cell array region CELL and some elements of a peripheral circuit region CORE/PERI, which are taken along lines A-A′, B-B′, and C-C′ of FIG. 1.

Referring to FIG. 4, isolation trenches 116T may be formed in the cell array region CELL and the peripheral circuit region CORE/PERI of the substrate 110, and isolation layers 116 may be formed in the isolation trenches 116T. Due to the isolation layers 116, active regions 118 may be defined in the cell array region CELL of the substrate 110, and active regions 119 may be defined in the peripheral circuit region CORE/PERI of the substrate 110.

The isolation layer 116 may include a first isolation layer 116A and a second isolation layer 116B. The first isolation layer 116A and the second isolation layer 116B may be formed of different materials. For example, the first isolation layer 116A may include an oxide layer, and the second isolation layer 116B may include a nitride layer. However, the isolation layer 116 according to the inventive concepts is not limited thereto. For example, the isolation layer 116 may be a single layer including one insulating layer or a multilayered structure including a combination of at least three insulating layers.

A plurality of word line trenches 120T may be formed in the cell array region CELL of the substrate 110. The plurality of word line trenches 120T may extend parallel to one another. Each of the plurality of word line trenches 120T may have a line shape that may run across the active region 118. As can be seen from a portion taken along the line B-B′, to form the plurality of word line trenches 120T having bottom surfaces with step differences, the isolation layers 116 and the substrate 110 may be etched by using separate etching processes so that the isolation layers 116 can have a different etch depth from the substrate 110.

After the resultant structure having the plurality of word line trenches 120T is cleaned, a gate dielectric layer 122, a plurality of word lines 120, and a plurality of buried insulating layers 124 may be sequentially formed in the plurality of word line trenches 120T.

In some example embodiments, after the plurality of word lines 120 are formed, impurity ions may be implanted into the substrate 110 on both sides of the plurality of word lines 120, thereby forming source and drain regions in top surfaces of the plurality of active regions 118. In some other embodiments, before the plurality of word lines 120 are formed, an impurity ion implantation process for forming the source and drain regions may be performed. In some example embodiments, the plurality of word lines 120 may be formed of Ti, TiN, Ta, TaN, W, WN, TiSiN, WSiN, or a combination thereof.

The gate dielectric layer 122 may include at least one selected from the group consisting of a silicon oxide layer, a silicon nitride layer, a silicon oxynitride layer, an oxide/nitride/oxide (ONO) layer, or a high-k dielectric layer having a higher dielectric constant than the silicon oxide layer. For example, the gate dielectric layer 122 may have a dielectric constant of about 10 to 25. In some example embodiments, the gate dielectric layer 122 may be formed of at least one material selected from the group consisting of hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), or lead scandium tantalum oxide (PbScTaO). For example, the gate dielectric layer 122 may be formed of HfO₂, Al₂O₃, HfAlO₃, Ta₂O₃, or TiO₂.

Top surfaces of the plurality of buried insulating layers 124 may be disposed at substantially the same level as a top surface of the substrate 110. The buried insulating layer 124 may include one material layer selected from the group consisting of a silicon oxide layer, a silicon nitride layer, a silicon oxynitride layer, or a combination thereof.

A first buffer insulating layer pattern 112 and a second buffer insulating layer pattern 114 may be sequentially formed in the cell array region CELL and the peripheral circuit region CORE/PERI on the substrate 110. The active region 118 of the cell array region CELL may be exposed by a plurality of holes H formed in the first buffer insulating layer pattern 112 and the second buffer insulating layer pattern 114.

Each of the first buffer insulating layer pattern 112 and the second buffer insulating layer pattern 114 may include a silicon oxide layer, a silicon nitride layer, or a combination thereof. In some example embodiments, the first buffer insulating layer pattern 112 may include a silicon oxide layer, and the second buffer insulating layer pattern 114 may include a silicon nitride layer.

The first buffer insulating layer pattern 112, the second buffer insulating layer pattern 114, and the substrate 110 may be partially etched, thereby forming a plurality of DC holes 132H to expose a source region 118S of the active region 118 of the cell array region CELL.

Referring to FIG. 5, the plurality of DC holes 132H may be filled with a conductive material, thereby forming a plurality of DC conductive patterns 132.

The DC conductive patterns 132 may be formed of silicon (Si), germanium (Ge), tungsten (W), tungsten nitride (WN), cobalt (Co), nickel (Ni), aluminum (Al), molybdenum (Mo), ruthenium (Ru), titanium (Ti), titanium nitride (TiN), tantalum (Ta), tantalum nitride (TaN), copper (Cu), or a combination thereof. The DC conductive patterns 132 may be formed by using a bottom-up method, such as a selective epitaxial growth (SEG) process, an electroplating process, or an electro-less deposition (ELD) process. In some example embodiments, the DC conductive patterns 132 may include an epitaxial silicon layer formed by using a bottom-up method, such as an epitaxial growth process. By forming the DC conductive patterns 132 using a bottom-up method, possibility of forming seams may be slim, so that DC conductive patterns 132 that are free from voids may be formed. Accordingly, when a plurality of bit lines are formed in a subsequent process, a conductive material for forming the bit lines may be unlikely to flow into the DC conductive patterns 132, so that highly reliable DC conductive patterns 132 may be formed. A method of forming the DC conductive patterns 132 according to the inventive concepts is not limited to the bottom-up method. For example, the DC conductive patterns 132 may be formed by using a top-down method, such as a chemical vapor deposition (CVD) process or an atomic layer deposition (ALD) process.

In an example of a method for forming the plurality of DC conductive patterns 132, a conductive material may be formed to fill the DC holes 132H to such a sufficient thickness to fill the DC holes 132H, and planarized to expose a top surface of the second buffer insulating layer pattern 114. Thus, each of the plurality of DC conductive patterns 132 may have a top surface 132T, which may extend on the same plane with the top surface of the second buffer insulating layer pattern 114.

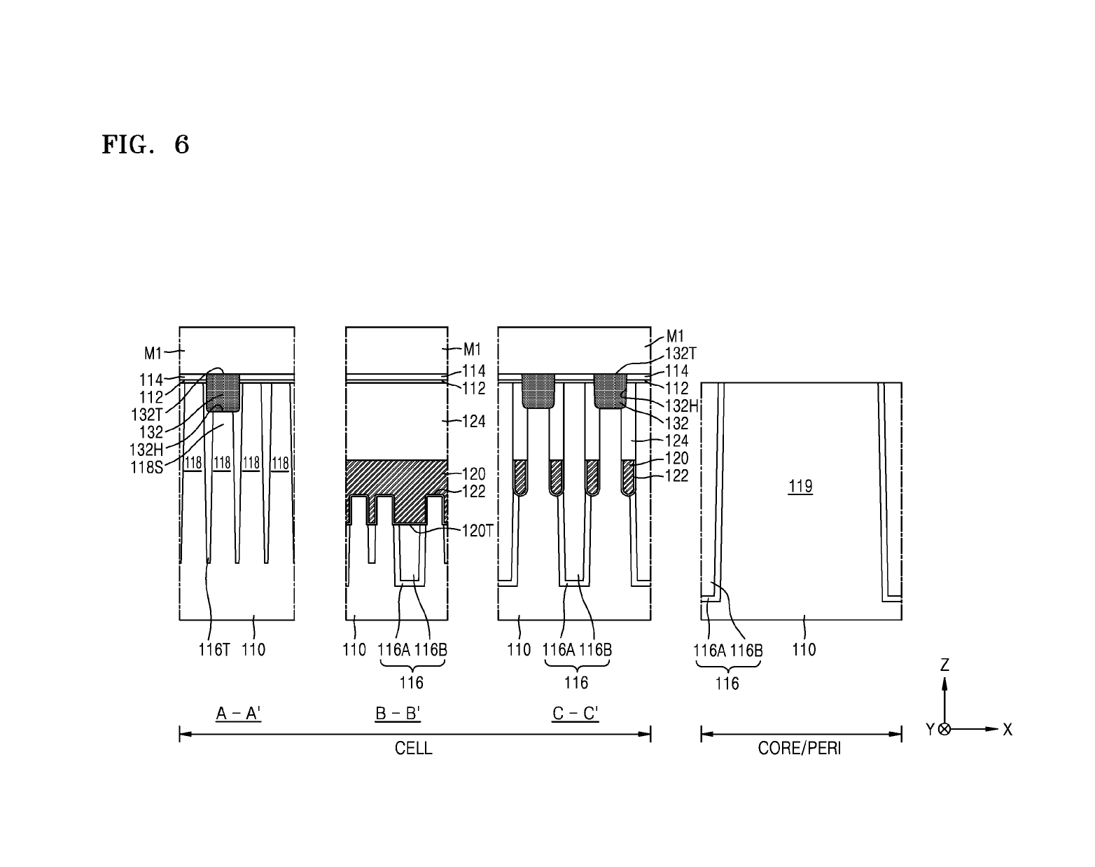

Referring to FIG. 6, portions of the first buffer insulating layer pattern 112 and the second buffer insulating layer pattern 114, which are disposed in the peripheral circuit region CORE/PERI, may be removed.

In an example of the removal process, a first mask pattern M1 may be formed to expose the portion of the second buffer insulating layer pattern 114 disposed in the peripheral circuit region CORE/PERI and cover the second buffer insulating layer pattern 114 in the cell array region CELL. The first buffer insulating layer 212 and the second buffer insulating layer 214 may be removed from the peripheral circuit region CORE/PERI by using the first mask pattern M1 as an etch mask, thereby exposing the active region 119 in the peripheral circuit region CORE/PERI.

To remove the first buffer insulating layer 212 and the second buffer insulating layer 214 from the peripheral circuit region CORE/PERI, a wet etching process or a dry etching process may be employed.

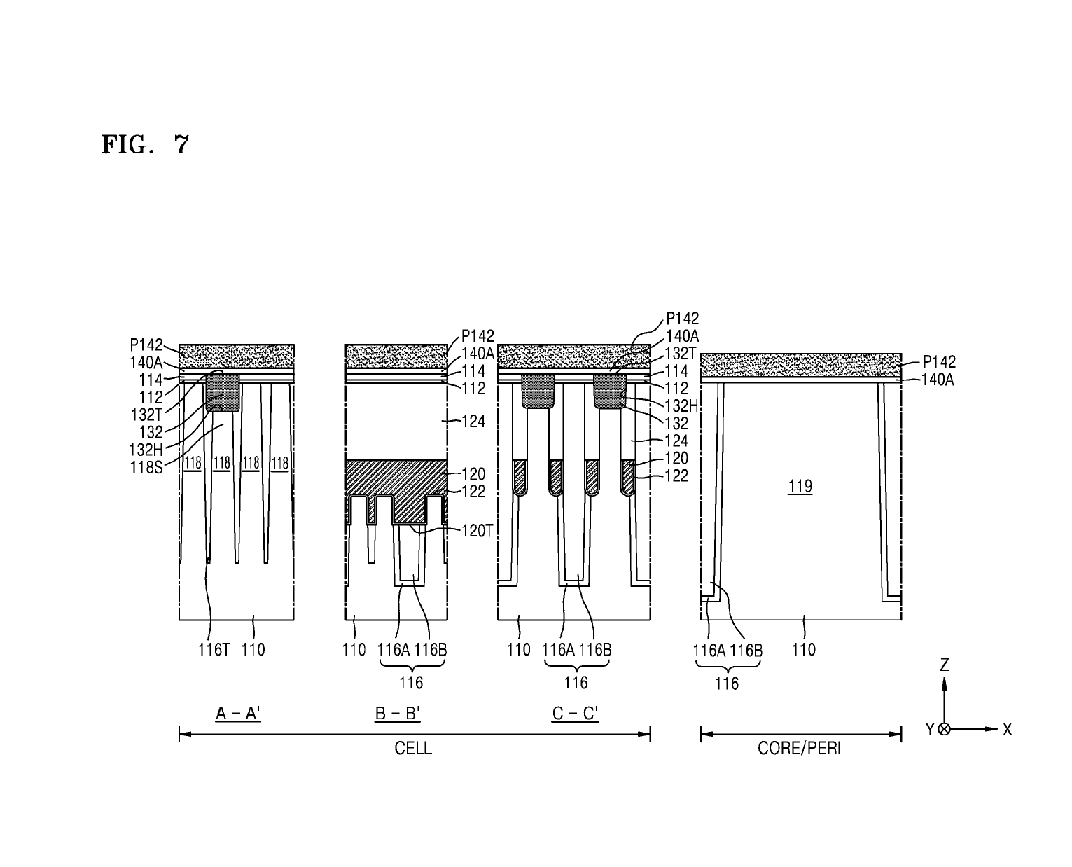

Referring to FIG. 7, after the first mask pattern M1 (refer to FIG. 6) is removed, a gate insulating layer 140A and a gate conductive layer P142 may be sequentially formed in the cell array region CELL and the peripheral circuit region CORE/PERI.

The gate insulating layer 140A and the gate conductive layer P142 may be formed to cover the top surface of the second buffer insulating layer pattern 114 and top surfaces of the DC conductive patterns 132 in the cell array region CELL, and to cover a top surface of the isolation layer 116 and the top surface of the active region 119 in the peripheral circuit region CORE/PERI.

The gate insulating layer 140A may include a silicon oxide layer, a silicon nitride layer, a silicon oxynitride layer, or a combination thereof.

The gate conductive layer P142 may be formed of a conductive poly-Si, a doped semiconductor material, a conductive metal nitride, or a metal silicide. Each of the gate insulating layer 140A and the gate conductive layer P142 may be formed by using a CVD process or an ALD process.

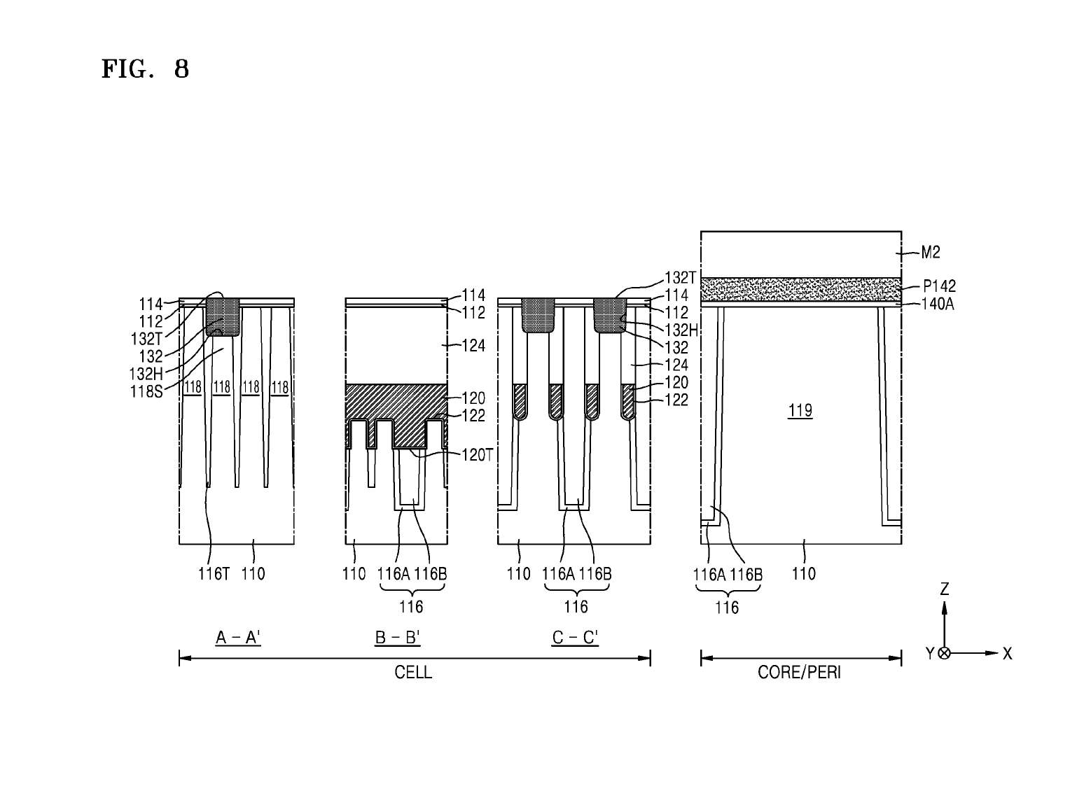

Referring to FIG. 8, the gate conductive layer P142 and the gate insulating layer 140A may be removed from the cell array region CELL to expose the top surface of the second buffer insulating layer pattern 114 and the top surfaces of the DC conductive patterns 132.

To remove the gate conductive layer P142 and the gate insulating layer 140A in the cell array region CELL, a second mask pattern M2 may be formed to expose the gate conductive layer P142 in the cell array region CELL and cover the gate conductive layer P142 in the peripheral circuit region CORE/PERI. The gate conductive layer P142 exposed in the cell array region CELL and the gate insulating layer 140A disposed thereunder may be sequentially etched by using the second mask pattern M2 as an etch mask.

In some example embodiments, the gate conductive layer P142 may be removed from the cell array region CELL by means of a dry etching process, and the gate insulating layer 140A may be removed by means of a wet etching process using a hydrofluoric (HF) solution.

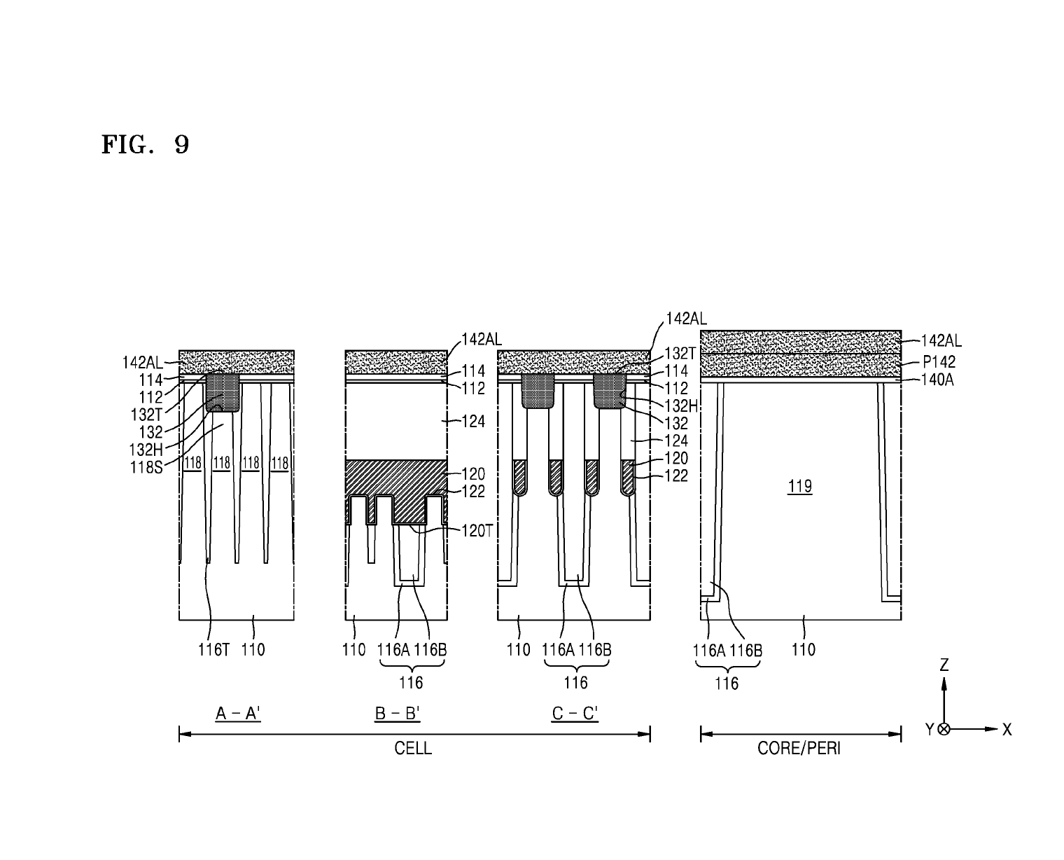

Referring to FIG. 9, a first bit line conductive layer 142AL may be formed to cover the top surface of the second buffer insulating layer pattern 114 and the top surfaces of the DC conductive pattern 132 in the cell array region CELL, and cover the gate conductive layer P142 in the peripheral circuit region CORE/PERI.

A top surface of a portion of the first bit line conductive layer 142AL disposed in the cell array region CELL may be at a lower level than a top surface of a portion of the first bit line conductive layer 142AL disposed in the peripheral circuit region CORE/PERI.

In some example embodiments, the first bit line conductive layer 142AL may be formed of the same material as the gate conductive layer P142. In some example embodiments, the first bit line conductive layer 142AL may be formed of conductive poly-Si, a doped semiconductor material, a conductive metal nitride, or a metal silicide. The first bit line conductive layer 142AL may be formed of a CVD process or an ALD process.

In some example embodiments, the first bit line conductive layer 142AL may be formed of the same material as DC conductive pattern 132.

In the cell array region CELL, the top surface 132T of the DC conductive pattern 132, which may extend on the same plane with the top surface of the second buffer insulating layer pattern 114, may be in direct contact with a bottom surface of the first bit line conductive layer 142AL. Thus, an interface between the DC conductive pattern 132 and the first bit line conductive layer 142AL may be formed along the top surface 132T of the DC conductive pattern 132 and extend on the same plane with the top surface of the second buffer insulating layer pattern 114.

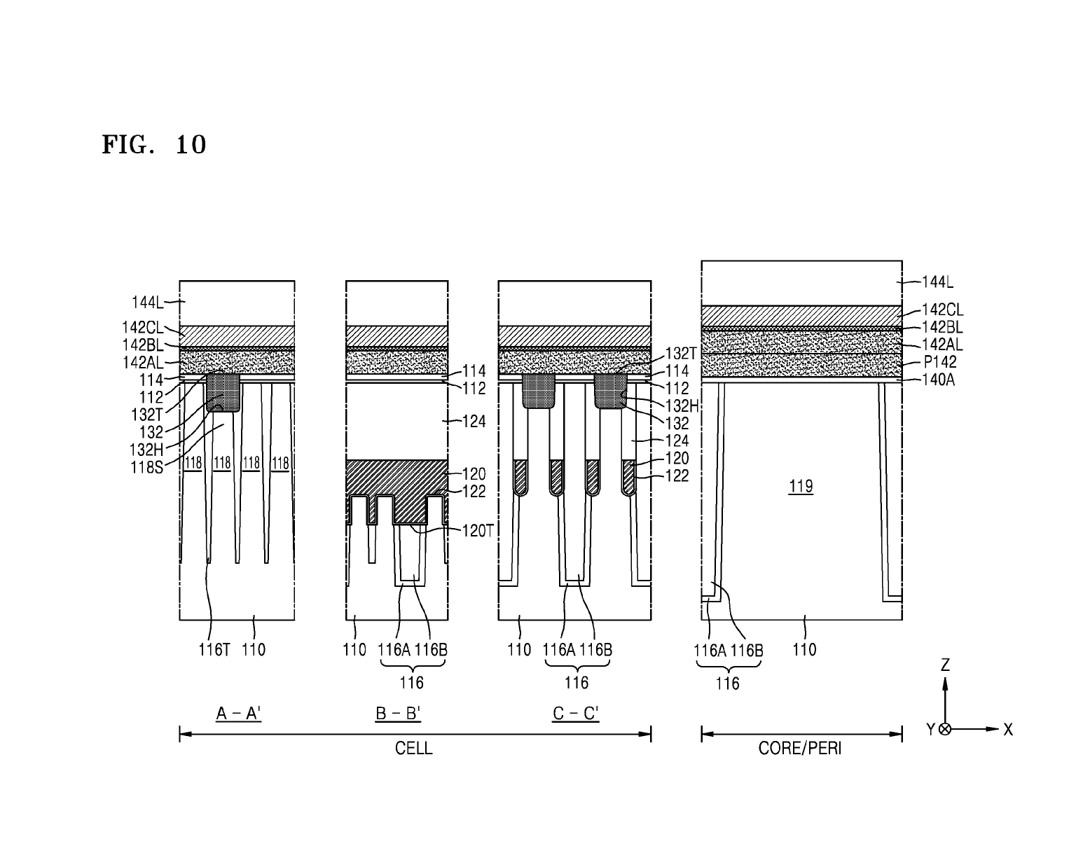

Referring to FIG. 10, in the cell array region CELL and the peripheral circuit region CORE/PERI, a second bit line conductive layer 142BL and a third bit line conductive layer 142CL may be sequentially formed to cover the first bit line conductive layer 142AL, and an insulating layer 144L for forming an insulating capping line may be formed on the third bit line conductive layer 142CL.

In some example embodiments, the second bit line conductive layer 142BL may be formed of titanium nitride (TiN), and the third bit line conductive layer 142CL may be formed of tungsten (W). The insulating layer 144L for forming the insulating capping line may be formed of a silicon oxide layer, a silicon nitride layer, or a combination thereof.

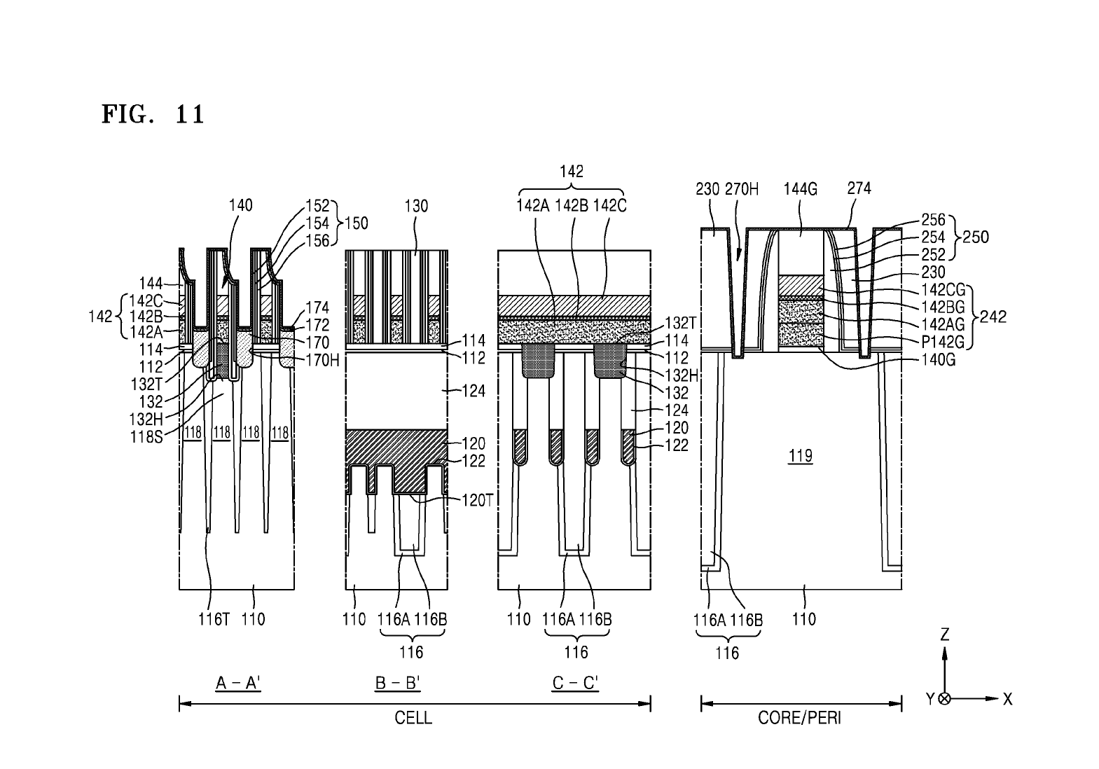

Referring to FIG. 11, in the cell array region CELL, the first bit line conductive layer 142AL, the second bit line conductive layer 142BL, the third bit line conductive layer 142CL, and the insulating layer 144L for forming the insulating capping line may be patterned, thereby forming a plurality of bit lines 142 including a first bit line conductive pattern 142A, a second bit line conductive pattern 142B, and a third bit line conductive pattern 142C and a plurality of insulating capping lines 144 covering the plurality of bit lines 142. Furthermore, in the peripheral circuit region CORE/PERI, the gate insulating layer 140A, the gate conductive layer P142, the first gate electrode conductive layer 142AL, the second gate electrode conductive layer 142BL, the third gate electrode conductive layer 142CL, and the insulating layer 144L for forming the insulating capping line may be patterned, thereby forming a gate electrode structure 242 including a gate insulating layer 140G, a gate conductive pattern P142G, a first gate electrode conductive pattern 142AG, a second gate electrode conductive pattern 142BG, and a third gate electrode conductive pattern 142CG, and an insulating capping line 144G covering the gate electrode structure 242.

Thereafter, a plurality of insulating spacer structures 150 may be formed to cover two sidewalls of the plurality of bit lines 142 and the plurality of insulating capping lines 144 in the cell array region CELL. The insulating spacer structures 150 may include first insulating spacers 152, second insulating spacers 154, and third insulating spacers 156.

Insulating patterns 130 may be formed in spaces defined by the insulating spacer structures 150 between the plurality of bit line structures 140, and define buried contact holes 170H. Buried contacts 170 may be formed to fill the buried contact holes 170H. The buried contact holes 170H may be formed to expose the active region 118. The buried contacts 170 may be formed by using a chemical vapor deposition (CVD) process, a physical vapor deposition (PVD) process, or a silicon epitaxial growth process. The buried contacts 170 may be formed of a doped semiconductor material, a conductive metal nitride, or a metal silicide, but the inventive concepts are not limited thereto.

Thereafter, the plurality of insulating capping lines 144, the plurality of insulating spacer structures 150, and the plurality of insulating patterns 130 may be partially etched, and a metal silicide layer 172 may be formed on exposed portions of top surfaces of the buried contacts 170. A conductive barrier layer 174 may be formed to cover a top surface of the metal silicide layer 172, portions of top surfaces of the insulating capping lines 144, and portions of the insulating spacer structures 150.

The metal silicide layer 172 may be formed of cobalt silicide (CoSix), nickel silicide (NiSix), or manganese silicide (MnSix), but the inventive concepts are not limited thereto.

The conductive barrier layer 174 may be formed of a metal-containing conductive material. For example, the conductive barrier layer 174 may have a Ti/TiN stack structure.

The process of forming the gate electrode structure 242 and the insulating capping line 144 in the peripheral circuit region CORE/PERI may be performed simultaneously with the process of forming the plurality of bit lines 142 and the plurality of insulating capping lines 144 in the cell array region CELL.

In the peripheral circuit region CORE/PERI, insulating spacer structures 250 may be formed to cover sidewalls of the gate electrode structure 242 and the insulating capping line 144. The insulating spacer structures 250 may include first insulating spacers 252, second insulating spacers 254, and third insulating spacers 256. The first insulating spacers 252, the second insulating spacers 254, and the third insulating spacers 256 formed in the peripheral circuit region CORE/PERI may be respectively formed of the same material at the same time as the first insulating spacer 152, the second insulating spacers 154, and the third insulating spacers 156 formed in the cell array region CELL.

In the peripheral circuit region CORE/PERI, an insulating layer 230 may be formed around the gate electrode structure 242, the insulating capping line 144, and the insulating spacer structure 250. The insulating layer 230 may be formed of a silicon oxide layer, a silicon nitride layer, or a combination thereof.

A mask pattern (not shown) may be formed on the insulating layer 230 in the peripheral circuit region CORE/PERI to cover the insulating layer 230 except for regions in which contact holes 270H will be formed. Portions of the insulating layer 230 may be etched by using the mask pattern as an etch mask, thereby forming the contact holes 270H. The active region 119 may be exposed through the contact holes 270H. The process of forming the contact holes 270H may be performed simultaneously with the process of forming the buried contact holes 170H of the cell array region CELL.

A conductive barrier layer 274 may be formed to cover an inner wall of the contact hole 270H. The process of forming the conductive barrier layer 274 may be performed simultaneously with the process of forming the conductive barrier layer 174 of the cell array region CELL. The conductive barrier layer 274 may be formed of the same material as the conductive barrier layer 174 of the cell array region CELL.

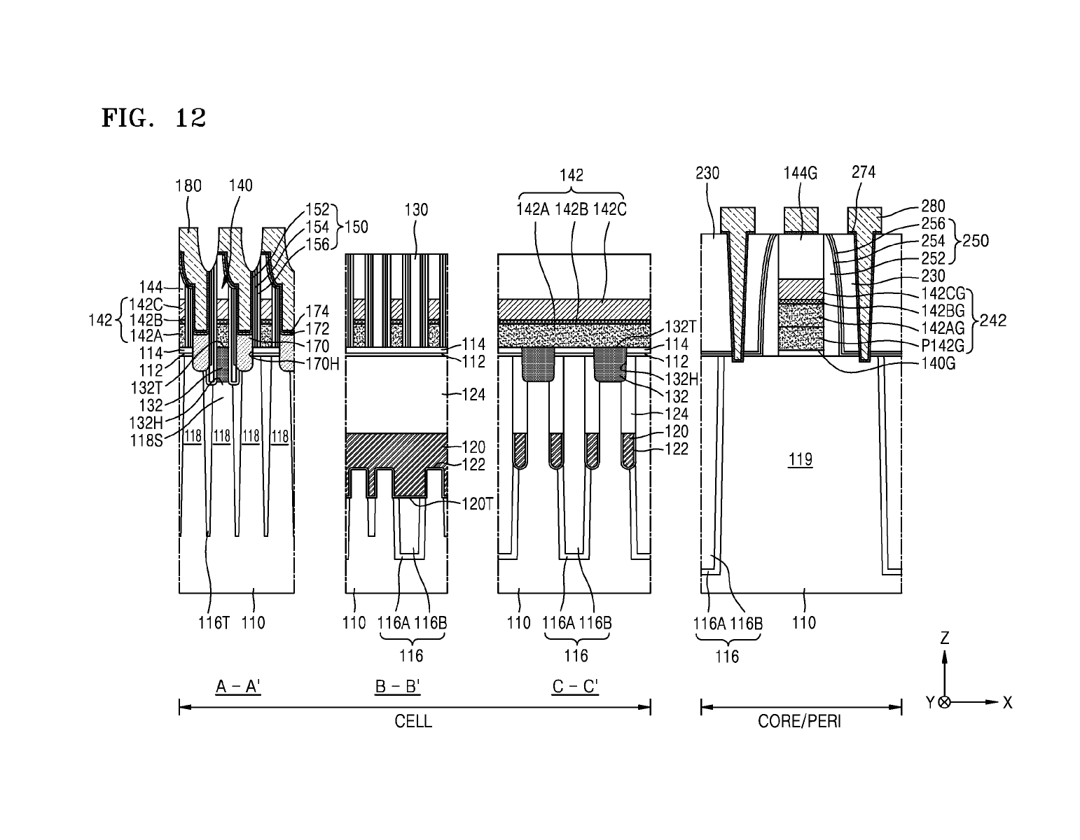

Referring to FIG. 12, landing pads 180 may be formed on the conductive barrier layer 174 in the cell array region CELL. The landing pads 180 may be electrically connected to the buried contacts 170 and extend from the insides of the buried contact holes 170H onto the plurality of bit line structures 140 to vertically overlap the plurality of bit line structures 140.

In the peripheral circuit region CORE/PERI, a conductive material may be deposited on the conductive barrier layer 274 to form conductive lines 280. The landing pads 180 of the cell array region CELL and the conductive lines 280 of the peripheral circuit region CORE/PERI may be simultaneously formed of the same material. The landing pads 180 and the conductive lines 280 may be formed by using a CVD process or a PVD process. In some example embodiments, the landing pads 180 and the conductive lines 280 may be formed of a metal, a metal nitride, conductive poly-Si, or a combination thereof. For example, the landing pads 180 and the conductive lines 280 may include tungsten (W).

FIGS. 13 through 17 are cross-sectional views of sequential processes of a method of manufacturing a semiconductor device according to other example embodiments of the inventive concepts. A method of manufacturing the semiconductor device 300 shown in FIG. 3 will be described with reference to FIGS. 13 through 17.

FIGS. 13 to 17 show cross-sectional views illustrating sequential processes of forming some elements of a cell array region CELL and some elements of a peripheral circuit region CORE/PERI, which are taken along lines A-A′, B-B′, and C-C′ of FIG. 1.

Referring to FIG. 13, similar processes to those described with reference to FIG. 4 may be performed until a first buffer insulating layer pattern 112, a second buffer insulating layer pattern 114, and a portion of the substrate 110 are etched to form a plurality of DC holes 132H exposing a source region 118S of an active region 118 in a cell array region CELL.

Thereafter, a bit line conductive layer 330 may be formed on the substrate 110 to fill the plurality of DC holes 132H and cover a top surface of the second buffer insulating layer pattern 114 in the cell array region CELL and a peripheral circuit region CORE/PERI.

In the cell array region CELL, the bit line conductive layer 330 may include a plurality of DC conductive patterns 332 and a first bit line conductive layer 342AL integrally connected to the plurality of DC conductive patterns 332.

In some example embodiments, the bit line conductive layer 330 may cover a top surface of the second buffer insulating layer pattern 114 to a thickness of about 100 Å to about 300 Å, but the inventive concepts are not limited thereto. The bit line conductive layer 330 may be formed by using a CVD process or an ALD process.

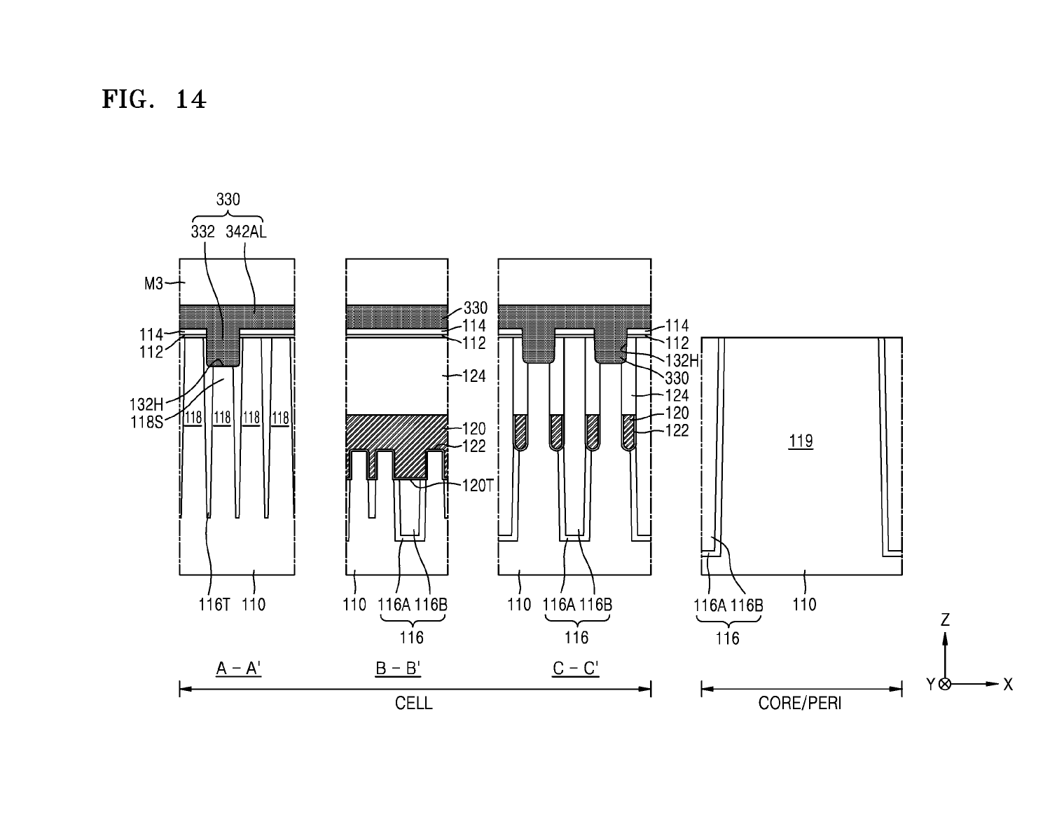

Referring to FIG. 14, portions of the first buffer insulating layer pattern 112, the second buffer insulating layer pattern 114, and the bit line conductive layer 330 disposed in the peripheral circuit region CORE/PERI may be removed to expose the active region 119.

As an example, a mask pattern M3 may be formed to expose the bit line conductive layer 330 in the peripheral circuit region CORE/PERI and cover the bit line conductive layer 330 in the cell array region CELL. The bit line conductive layer 330, a second buffer insulating layer 214, and a first buffer insulating layer 212 may be removed from the peripheral circuit region CORE/PERI by performing a dry or wet etching process using the mask pattern M3 as an etch mask. Thus, the active region 119 may be exposed.

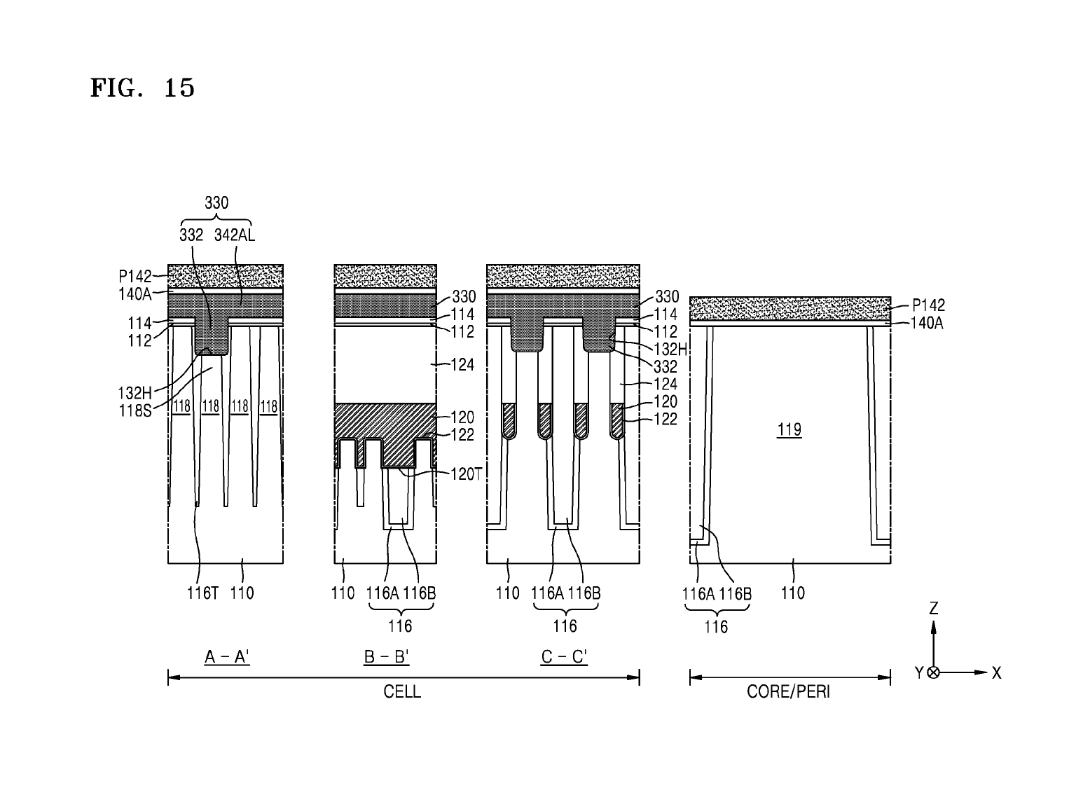

Referring to FIG. 15, after the mask pattern M3 (refer to FIG. 14) is removed, a gate insulating layer 140A and a gate conductive layer P142 may be sequentially formed on the bit line conductive layer 330 in both the cell array region CELL and the peripheral circuit region CORE/PERI, by using similar processes to those described with reference to FIG. 7.

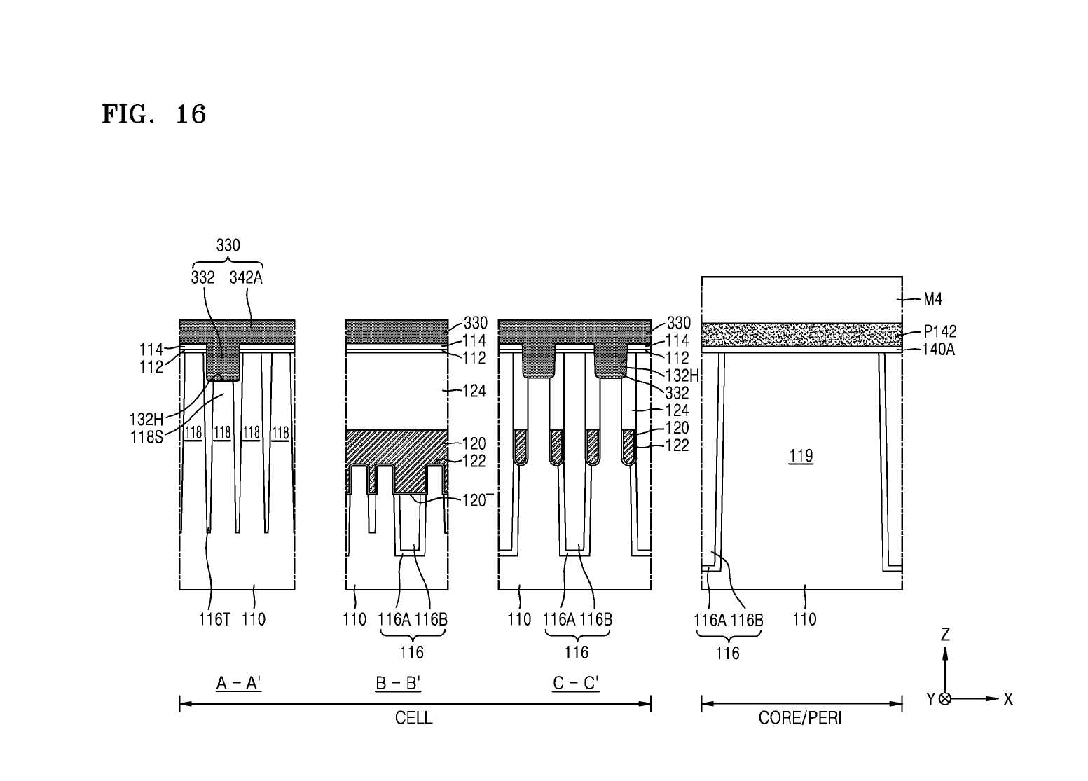

Referring to FIG. 16, portions of the gate insulating layer 140A and the gate conductive layer P142, which are disposed in the cell array region CELL, may be removed.

In an example of the removal process, a mask pattern M4 may be formed to expose the gate conductive layer P142 in the cell array region CELL and cover the gate conductive layer P142 in the peripheral circuit region CORE/PERI. Thereafter, the gate conductive layer P142 and the gate insulating layer 140A may be removed using an etching process from the cell array region CELL using the mask pattern M4 as an etch mask so that the bit line conductive layer 330 may be exposed again in the cell array region CELL.

In the cell array region CELL, the gate conductive layer P142 may be removed using a dry etching process, and the gate insulating layer 140A may be removed by a wet etching process using a hydrofluoric (HF) solution.

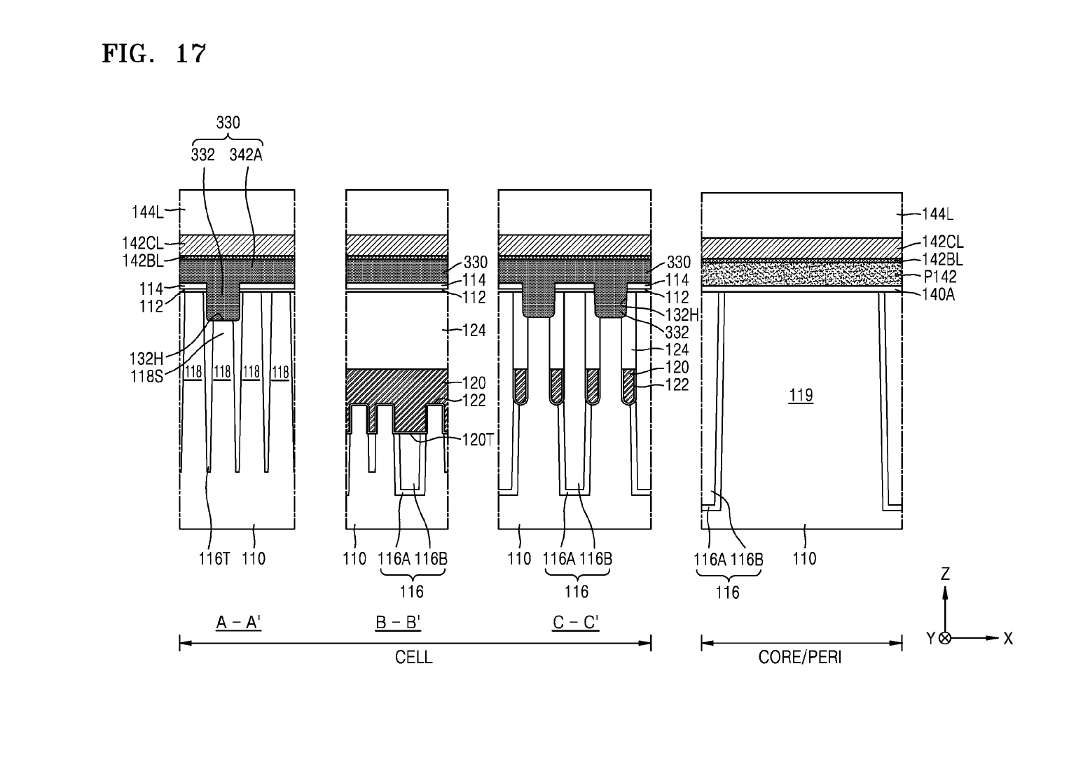

Referring to FIG. 17, after the mask pattern M4 (refer to FIG. 16) is removed, a second bit line conductive layer 142BL and a third bit line conductive layer 142CL may be sequentially formed to cover the bit line conductive layer 330 in both the cell array region CELL and the peripheral circuit region CORE/PERI, by using similar processes to those described with reference to FIG. 10. Thereafter, an insulating layer 144L for forming an insulating capping line may be formed on the third bit line conductive layer 142CL.

Subsequently, similar processes to the processes described with reference to FIGS. 11 to 14 may be performed, thereby completing the manufacture of the semiconductor device 300 shown in FIG. 3.

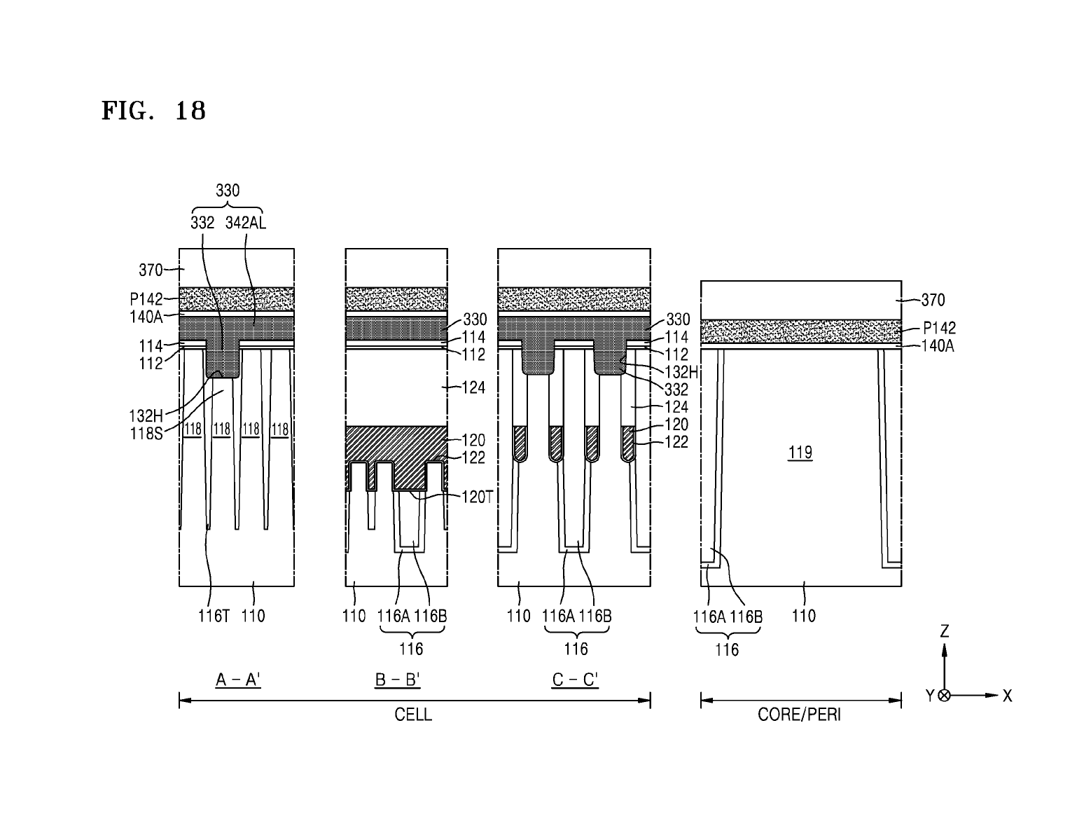

FIGS. 18 to 20 are cross-sectional views of sequential processes of a method of manufacturing a semiconductor device according to other example embodiments of the inventive concepts. A method of manufacturing the semiconductor device 300 shown in FIG. 3, according to other example embodiments of the inventive concepts, will now be described with reference to FIGS. 18 to 20.

Referring to FIG. 18, similar processes to those described with reference to FIGS. 13 to 15 may be performed until a gate insulating layer 140A for a peripheral circuit and a gate conductive layer P142 are sequentially formed in a cell array region CELL and a peripheral circuit region CORE/PERI.

Thereafter, a mask layer 370 may be formed on the gate conductive layer P142 in both the cell array region CELL and the peripheral circuit region CORE/PERI.

In some example embodiments, when the gate conductive layer P142 is formed of conductive poly-Si, the mask layer 370 may be formed of silicon oxide, but is not limited thereto. The mask layer 370 may be conformally formed to a generally uniform thickness along a stepped profile of a top surface of the gate conductive layer P142.

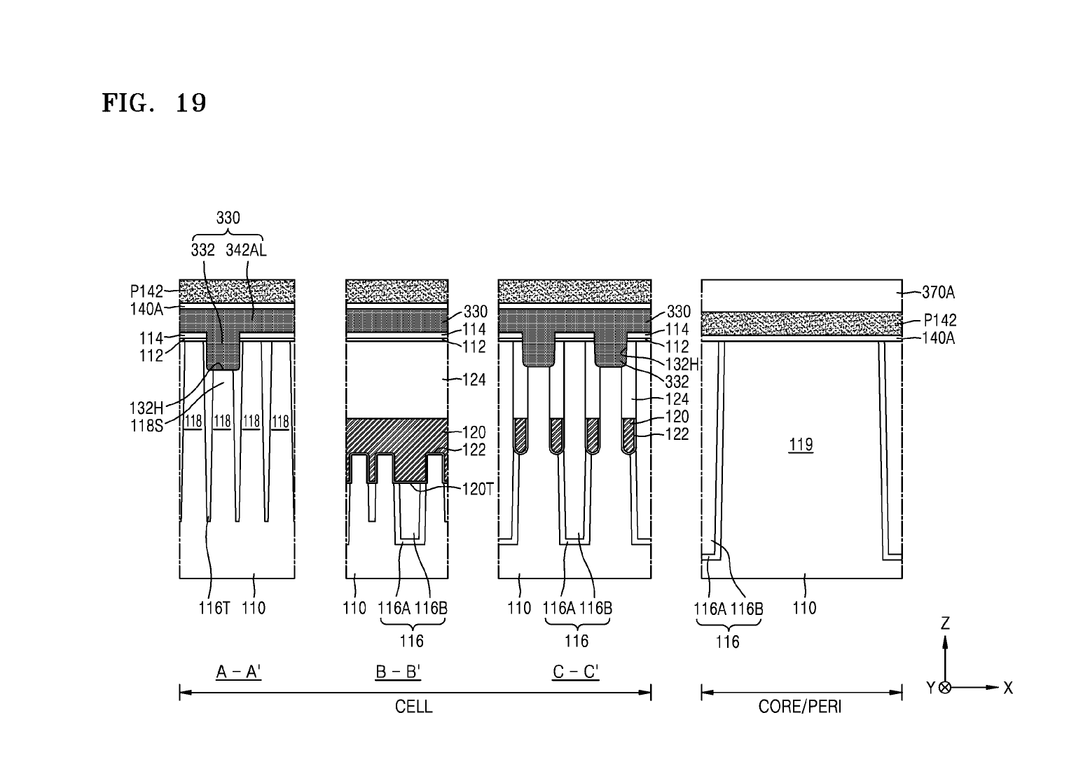

Referring to FIG. 19, the mask layer 370 may be planarized in the cell array region CELL and the peripheral circuit region CORE/PERI until the gate conductive layer P142 is exposed in the cell array region CELL so that the planarized mask pattern 370a may remain in the peripheral circuit region CORE/PERI.

The top surface of the gate conductive layer P142 may have a step difference in the cell array region CELL and the peripheral circuit region CORE/PERI. For example, the top surface of the gate conductive layer P142 may have a smaller height in the peripheral circuit region CORE/PERI than in the cell array region CELL. Thus, after the mask layer 370 is planarized, the planarized mask pattern 370A may remain only in the peripheral circuit region CORE/PERI.

In some example embodiments, the mask layer 370 may be planarized by using a chemical mechanical polishing (CMP) process.

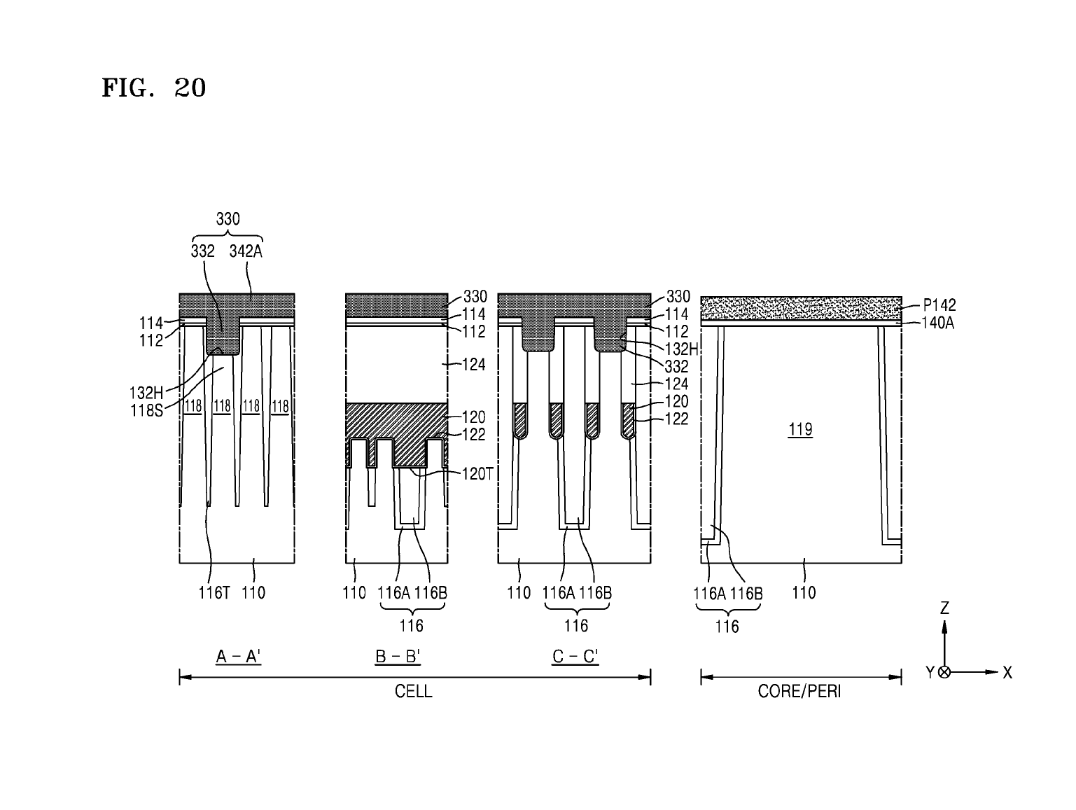

Referring to FIG. 20, the gate conductive layer P142 may be removed using an etching process from the cell array region CELL by using the planarized mask pattern 370A as an etch mask. Thereafter, the gate insulating layer 140A exposed in the cell array region CELL and the planarized mask pattern 370A may be removed so that a bit line conductive layer 330 may be exposed again in the cell array region CELL.

In some example embodiments, the gate conductive layer P142 disposed in the cell array region CELL may be removed by using a dry etching process, and the gate insulating layer 140A disposed in the cell array region CELL and the planarized mask pattern 370A disposed in the peripheral circuit region CORE/PERI may be removed by using a wet etching process. In some example embodiments, the gate insulating layer 140A disposed in the cell array region CELL and the planarized mask pattern 370A disposed in the peripheral circuit region CORE/PERI may be simultaneously removed.

Subsequently, similar processes to the processes described with reference to FIG. 17 or FIGS. 11 to 14 may be performed, thereby completing the manufacture of the semiconductor device 300 shown in FIG. 3.

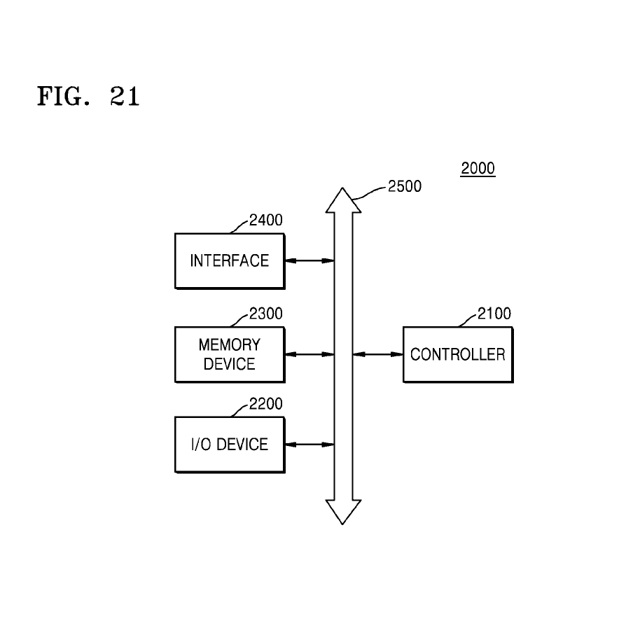

FIG. 21 is a diagram of a system 2000 including a semiconductor device according to an example embodiment of the inventive concepts.

The system 2000 may include a controller 2100, an input/output (I/O) device 220, a memory device 2300, and an interface 2400. The system 2000 may be a mobile system or a system configured to transmit or receive information. In some example embodiments, the mobile system may be a personal digital assistant (PDA), a portable computer, a web tablet, a wireless phone, a mobile phone, a digital music player, or a memory card. The controller 2100 may be configured to control an execution program in the system 2000 and include a microprocessor, a digital signal processor, a microcontroller, or devices similar thereto. The I/O device 2200 may be used to input or output data of the system 2000. The system 2000 may be connected to an external device (e.g., a personal computer (PC) or a network) using the I/O device 2200 and exchange data with the external device. The I/O device 2200 may be, for example, a keypad, a keyboard, or a display device.

The memory device 2300 may store codes and/or data for operations of the controller 2100 or store data processed by the controller 2100. The memory device 2300 may include at least one of the semiconductor devices 200 and 300 described with reference to FIGS. 1 through 20 according to example embodiments of the inventive concepts or at least one of modified or changed semiconductor devices thereof within the spirit and scope of the inventive concepts.

The interface 2400 may be a data transmission path between the system 2000 and another external device. The controller 2100, the I/O device 2200, the memory device 2300, and the interface 2400 may communicate with one another through a bus 2500. The system 2000 may be used for a mobile phone, an MPEG-1 audio layer 3 (MP3) player, a navigation device, a portable multimedia player (PMP), a solid-state disk (SSD), or household appliances.

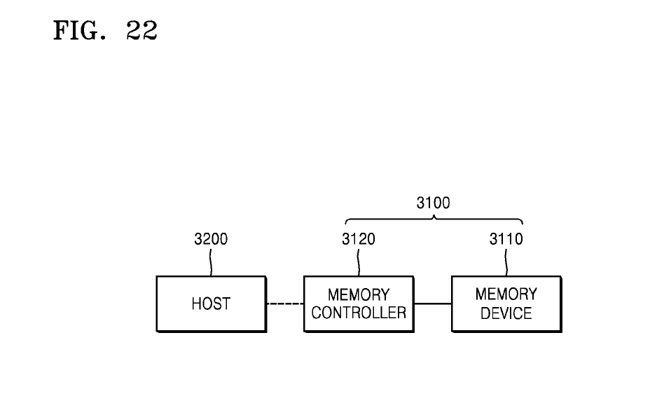

FIG. 22 is a diagram of a memory card 3100 including a semiconductor device according to an example embodiment of the inventive concepts.

The memory card 3100 may include a memory device 3110 and a memory controller 3120.

The memory device 3110 may store data. In some example embodiments, the memory device 3110 may be a non-volatile device capable of retaining stored data even if power supply is interrupted. The memory device 3110 may include at least one of the semiconductor devices 200 and 300 described with reference to FIGS. 1 to 20 according to example embodiments of the inventive concepts or at least one of modified or changed semiconductor devices thereof within the spirit and scope of the inventive concepts.

The memory controller 3120 may read data stored in the memory device 3110 or store data in the memory device 3110 in response to read/write requests of a host 3200. The memory controller 3120 may include at least one of the semiconductor devices 200 and 300 described with reference to FIGS. 1 through 20 according to example embodiments of the inventive concepts or at least one of modified or changed semiconductor devices thereof within the spirit and scope of the inventive concepts.

While the inventive concepts have been particularly shown and described with reference to example embodiments thereof, it will be understood that various changes in form and details may be made therein without departing from the spirit and scope of the following claims.

What is claimed is:

1. A semiconductor device comprising:
a substrate including a cell array region having a first active region and a peripheral circuit region having a second active region;
an insulating layer pattern on the substrate in the cell array region, the insulating layer pattern including a hole corresponding with the first active region;
a direct contact (DC) conductive pattern in the hole and connected to the first active region in the cell array region, the DC conductive pattern buried in the substrate;
a bit line connected to the DC conductive pattern in the cell array region, the bit line including a first bit line conductive pattern contacting the DC conductive pattern and covering a top surface of the insulating layer pattern;
a gate insulating layer on the second active region in the peripheral circuit region; and
a gate electrode structure on the gate insulating layer in the peripheral circuit region, the gate electrode structure including a gate conductive pattern contacting the gate insulating layer, and a first gate electrode conductive pattern on the gate conductive pattern, the first gate electrode conductive pattern including a same material as the first bit line conductive pattern.

2. The semiconductor device of claim 1, wherein
the DC conductive pattern has a top surface that extends on a same plane as the top surface of the insulating layer pattern, and
the first bit line conductive pattern has a bottom surface contacting the top surface of the DC conductive pattern.

3. The semiconductor device of claim 1, wherein the DC conductive pattern is integrally connected to the first bit line conductive pattern.

4. The semiconductor device of claim 1, wherein
the first bit line conductive pattern has a first thickness in a first direction perpendicular to the substrate, and
a sum of thicknesses of the gate conductive pattern and the first gate electrode conductive pattern obtained in the first direction is greater than the first thickness.

5. The semiconductor device of claim 1, wherein the DC conductive pattern includes an epitaxial silicon layer.

6. The semiconductor device of claim 1, wherein the DC conductive pattern and the first bit line conductive pattern include a same material.

7. The semiconductor device of claim 1, wherein
the bit line further comprises a second bit line conductive pattern and a third bit line conductive pattern sequentially formed on the first bit line conductive pattern,
the gate electrode structure further comprises a second gate electrode conductive pattern and a third gate electrode conductive pattern sequentially formed on the first gate electrode conductive pattern,
the second gate electrode conductive pattern includes a same material as the second bit line conductive pattern, and
the third gate electrode conductive pattern includes a same material as the third bit line conductive pattern.

8. The semiconductor device of claim 7, wherein
the DC conductive pattern includes an epitaxial silicon layer, and
each of the first bit line conductive pattern, the gate conductive pattern, and the first gate electrode conductive pattern includes conductive poly-Si.

9. A semiconductor device comprising:
an insulating layer pattern on an active region in a substrate, the insulating layer pattern including a hole exposing the active region;
an epitaxial silicon pattern filling the hole and connected to the active region, the epitaxial silicon pattern buried in the substrate; and
a bit line connected to the epitaxial silicon pattern, the bit line including at least one conductive pattern contacting the epitaxial silicon pattern.

10. The semiconductor device of claim 9, wherein
the epitaxial silicon pattern has a top surface that extends on a same plane as the top surface of the insulating layer pattern, and
the conductive pattern has a bottom surface contacting the top surface of the epitaxial silicon pattern.

11. The semiconductor device of claim 9, wherein the epitaxial silicon pattern is integrally connected to the conductive pattern.

12. The semiconductor device of claim 9, wherein the epitaxial silicon pattern and the conductive pattern include a same material.

13. The semiconductor device of claim 9, wherein the conductive pattern includes conductive poly-Si.
